(19) United States
(12) Patent Application Publication
(10) Pub. No.: US 2025/0159900 A1
(43) Pub. Date: May 15, 2025

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Hitoshi KUNITAKE, Machida, Tokyo (JP); Fumito ISAKA, Zama, Kanagawa (JP); Tatsuya ONUKI, Atsugi, Kanagawa (JP); Shunpei YAMAZAKI, Setagaya, Tokyo (JP)

(21) Appl. No.: 18/839,097

(22) PCT Filed: Feb. 13, 2023
(86) PCT No.: PCT/IB2023/051253

§ 371 Date: Aug. 16, 2024

(30) Foreign Application Priority Data
Feb. 25, 2022 (JP) 2022-028041

(51) Int. Cl. H10B 53/30; H10B 53/20

(52) U.S. Cl. CPC H10B 53/30; H10B 53/20

(57) ABSTRACT

A semiconductor device that can be miniaturized or highly integrated is provided. The semiconductor device includes a first transistor that includes a first conductor, a first insulator, a first metal oxide, a second insulator, a second conductor, and a third conductor and a fourth conductor which cover parts of a top surface and parts of a side surface of the first metal oxide, which are stacked in this order from the bottom. A second transistor includes a fifth conductor, the first insulator, a second metal oxide, a third insulator, a sixth conductor, and a seventh conductor and a eighth conductor which cover parts of a top surface and parts of a side surface of the second metal oxide, which are stacked in this order from the bottom. A third transistor includes a ninth conductor, the first insulator, the second metal oxide, a fourth insulator, a tenth conductor, an eighth conductor, and an eleventh conductor covering part of the top surface and part of the side surface of the second metal oxide, which are stacked in this order from the bottom. One electrode of a capacitor including a material that can have ferroelectricity is electrically connected to the third conductor and the sixth conductor.

### TECHNICAL FIELD

One embodiment of the present invention relates to a semiconductor device, a memory device, and an electronic device. Another embodiment of the present invention relates to a method for manufacturing a semiconductor device.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a method for driving any of them, and a method for manufacturing any of them.

Note that in this specification and the like, a semiconductor device generally means a device that can function by utilizing semiconductor characteristics. A semiconductor element such as a transistor, a semiconductor circuit, an arithmetic device, and a memory device are each one embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

### BACKGROUND ART

In recent years, semiconductor devices such as an LSI (Large Scale Integration), a CPU (Central Processing Unit), and a memory (a memory device) have been developed. These semiconductor devices have been used in various electronic devices such as computers and portable information terminals. In addition, memories under development employ various memory systems for intended uses such as temporary storage at the time of executing arithmetic processing and long-term storage of data. Examples of memories with typical memory systems include a DRAM (Dynamic Random Access Memory), an SRAM (Static Random Access Memory), and a flash memory.

With an increasing amount of data to process, a semiconductor device having a larger memory capacity has been required. Patent Document 1 and Non-Patent Document 1 disclose memory cells formed by stacking transistors.

### REFERENCES

### Patent Document

[Patent Document 1] PCT International Publication No. 2021/053473

### Non-Patent Document

[Non-Patent Document 1] M. Oota et. al, “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be miniaturized or highly integrated. An object of one embodiment of the present invention is to provide a semiconductor device with high operating speed. An object of one embodiment of the present invention is to provide a semiconductor device having favorable electrical characteristics. An object of one embodiment of the present invention is to provide a semiconductor device with a small variation in electrical characteristics of transistors. An object of one embodiment of the present invention is to provide a highly reliable semiconductor device.

An object of one embodiment of the present invention is to provide a semiconductor device with high on-state current. An object of one embodiment of the present invention is to provide a semiconductor device with low power consumption. An object of one embodiment of the present invention is to provide a novel semiconductor device.

An object of one embodiment of the present invention is to provide a method for manufacturing a semiconductor device with a small number of processing steps.

An object of one embodiment of the present invention is to provide a memory device having a large memory capacity. An object of one embodiment of the present invention is to provide a memory device occupying a small area. An object of one embodiment of the present invention is to provide a highly reliable memory device. An object of one embodiment of the present invention is to provide a memory device with low power consumption. An object of one embodiment of the present invention is to provide a novel memory device.

Note that the description of these objects does not preclude the existence of other objects. One embodiment of the present invention achieves one or more of these objects and does not have to achieve all of these objects. Other objects can be derived from the description of the specification, the drawings, and the claims.

### Means for Solving the Problems

One embodiment of the present invention is a semiconductor device including a first transistor, a second transistor, and a capacitor. The first transistor includes a first insulator, a first metal oxide over the first insulator, a second insulator over the first metal oxide, a first conductor over the second insulator, a second conductor covering part of a top surface and part of a side surface of the first metal oxide, and a third conductor covering part of the top surface and part of the side surface of the first metal oxide. The second transistor includes the first insulator, the first metal oxide over the first insulator, a third insulator over the first metal oxide, a fourth conductor over the third insulator, the third conductor, and a fifth conductor covering part of the top surface and part of the side surface of the first metal oxide. The third conductor is shared by the first transistor and the second transistor. The first metal oxide is shared by the first transistor and the second transistor. The first metal oxide includes a channel formation region of the first transistor and a channel formation region of the second transistor. The first insulator includes a region overlapping with the first metal oxide. The capacitor includes a sixth conductor, a seventh conductor, and a material that can have ferroelectricity between the sixth conductor and the seventh conductor. The first conductor and the sixth conductor are electrically connected to each other.

In the above structure, the material that can have ferroelectricity is preferably one or more selected from hafnium oxide, zirconium oxide, and HfZrO_{X} (X is a real number greater than 0).

In the above structure, the material that can have ferroelectricity is preferably a material containing oxygen, hafnium, and zirconium.

In the above structure, the material that can have ferroelectricity is preferably a material where one or more selected from zirconium, silicon, aluminum, gadolinium, yttrium, lanthanum, and strontium are added to hafnium oxide.

In the above structure, the material that can have ferroelectricity is preferably a material where one or more selected from hafnium, silicon, aluminum, gadolinium, yttrium, lanthanum, and strontium are added to zirconium oxide.

In the above structure, an eighth conductor includes a region interposed between the sixth conductor and a tenth conductor in a plan view.

In the above structure, the semiconductor device preferably includes a third transistor. The first insulator preferably contains a material that can have ferroelectricity. The third transistor preferably includes an eighth conductor, the first insulator over the eighth conductor, a second metal oxide over the first insulator, a fifth insulator over the second metal oxide, a ninth conductor over the fifth insulator, and the sixth conductor covering part of a top surface and part of a side surface of the second metal oxide. The sixth conductor preferably includes a region in contact with a top surface of the first insulator. The seventh conductor preferably includes a region in contact with a bottom surface of the first insulator. The eighth conductor preferably includes a region in contact with the bottom surface of the first insulator. The first insulator preferably includes a region overlapping with the second metal oxide and a region overlapping with the seventh conductor.

In the above structure, the seventh conductor and the eighth conductor each preferably contain titanium nitride.

In the above structure, the semiconductor device preferably includes a plurality of memory layers stacked sequentially. Each of the plurality of memory layers preferably includes the first transistor, the second transistor, and the capacitor. The fifth conductor of the second transistor included in each of the plurality of memory layers is preferably electrically connected to the fifth conductor of the second transistor included in another memory layer.

### Effect of the Invention

According to one embodiment of the present invention, a semiconductor device that can be miniaturized or highly integrated can be provided. According to one embodiment of the present invention, a semiconductor device with high operating speed can be provided. According to one embodiment of the present invention, a semiconductor device having favorable electrical characteristics can be provided. According to one embodiment of the present invention, a semiconductor device with a small variation in electrical characteristics of transistors can be provided. According to one embodiment of the present invention, a highly reliable semiconductor device can be provided. According to one embodiment of the present invention, a semiconductor device with high on-state current can be provided. According to one embodiment of the present invention, a semiconductor device with low power consumption can be provided. According to one embodiment of the present invention, a novel semiconductor device can be provided.

According to one embodiment of the present invention, a method for manufacturing a semiconductor device with a small number of processing steps can be provided.

According to one embodiment of the present invention, a memory device having a large memory capacity can be provided. According to one embodiment of the present invention, a memory device occupying a small area can be provided. According to one embodiment of the present invention, a highly reliable memory device can be provided. According to one embodiment of the present invention, a memory device with low power consumption can be provided. According to one embodiment of the present invention, a novel memory device can be provided.

Note that the description of these effects does not preclude the existence of other effects. One embodiment of the present invention achieves one or more of these effects, and does not need to have all of these effects. Other effects can be derived from the description of the specification, the drawings, and the claims.

### BRIEF DESCRIPTION OF THE DRAWINGS

FIG. 1A and FIG. 1B are diagrams illustrating an example of a memory device.

FIG. 2A is a diagram illustrating a circuit structure example of memory cells. FIG. 2B is a graph showing polarization amount.

FIG. 3A, FIG. 3B, FIG. 3C, FIG. 3D, and FIG. 3E are diagrams illustrating an operation example of a memory cell.

FIG. 4 is a diagram illustrating an operation example of a memory cell.

FIG. 5A, FIG. 5B, and FIG. 5C are diagrams illustrating an operation example of a memory cell.

FIG. 6A, FIG. 6B, and FIG. 6C are diagrams illustrating an operation example of a memory cell.

FIG. 7 is a diagram illustrating a structure example of a memory cell.

FIG. 8 is a cross-sectional view illustrating a structure example of a semiconductor device.

FIG. 9 is a cross-sectional view illustrating a structure example of a semiconductor device.

FIG. 10A is a cross-sectional diagram illustrating a structure example of a semiconductor device.

FIG. 10B is a cross-sectional diagram illustrating a structure example of a transistor.

FIG. 11 is a cross-sectional view illustrating a structure example of a semiconductor device.

FIG. 12 is a cross-sectional view illustrating a structure example of a semiconductor device.

FIG. 13 is a diagram illustrating a structure example of a semiconductor device.

FIG. 14 is a diagram illustrating a structure example of a semiconductor device.

FIG. 15 is a cross-sectional view illustrating a structure example of a semiconductor device.

FIG. 16A and FIG. 16B are plan views illustrating a structure example of a semiconductor device.

FIG. 17A and FIG. 17B are plan views illustrating structure examples of a semiconductor device.

FIG. 18A and FIG. 18B are diagrams illustrating a structure example of a semiconductor device.

FIG. 19A and FIG. 19B are diagrams illustrating examples of electronic components.

FIG. 20A to FIG. 20J are diagrams illustrating examples of electronic devices.

FIG. 21A to FIG. 21E are diagrams illustrating examples of electronic devices.

FIG. 22A to FIG. 22C are diagrams illustrating examples of electronic devices.

FIG. 23 is a diagram illustrating an example of a device for space.

### MODE FOR CARRYING OUT THE INVENTION

Embodiments are described in detail with reference to the drawings. Note that the present invention is not limited to the following description, and it is readily understood by those skilled in the art that modes and details of the present invention can be changed in various ways without departing from the spirit and scope thereof. Thus, the present invention should not be interpreted as being limited to the description of the embodiments given below.

Note that in the structures of the invention described below, the same reference numerals are used in common for the same portions or portions having similar functions in different drawings, and repeated description thereof is omitted. The same hatching pattern is applied to portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

The term “film” and the term “layer” can be interchanged with each other depending on the case or circumstances. For example, the term “conductive layer” can be replaced with the term “conductive film”. For another example, the term “insulating film” can be replaced with the term “insulating layer”.

In this specification and the like, terms for describing positioning, such as “over,” “under,” “above,” and “below,” are sometimes used for convenience to describe the positional relation between components with reference to drawings. The positional relation between components is changed as appropriate in accordance with a direction in which each component is described. Thus, the positional relation is not limited to the terms described in this specification and the like, and can be described with another term as appropriate depending on the situation. For example, the expression “an insulator positioned over (on) a conductor” can be replaced with the expression “an insulator positioned under (on) a conductor” when the direction of a drawing illustrating these components is rotated by 180°.

### Embodiment 1

In this embodiment, a memory device of one embodiment of the present invention will be described with reference to drawings.

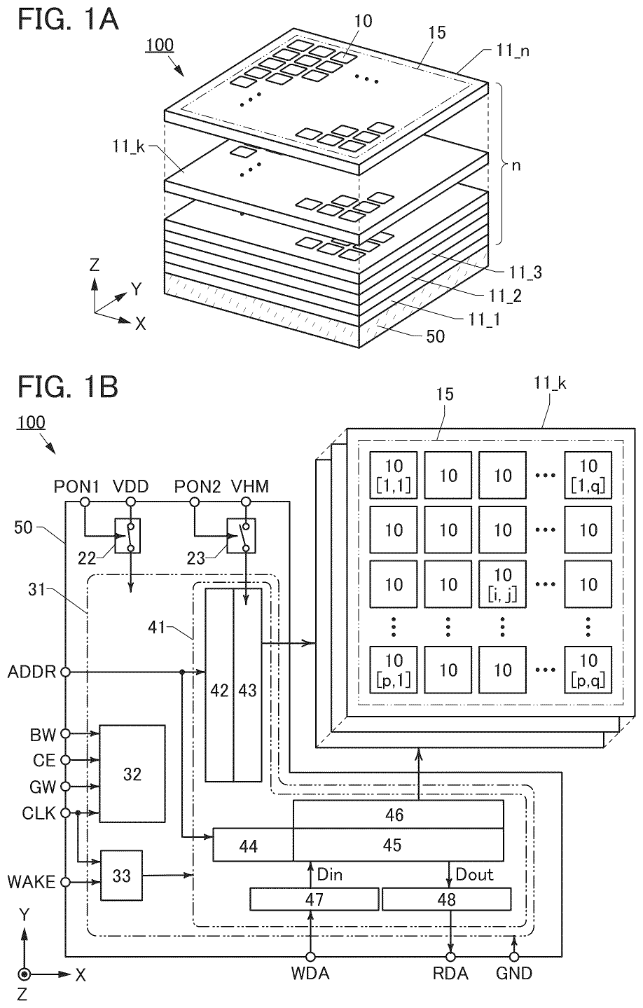

FIG. 1A is a schematic perspective view of the memory device of one embodiment of the present invention. FIG. 1B is a block diagram of the memory device of one embodiment of the present invention.

A memory device 100 illustrated in FIG. 1A and FIG. 1B includes a driver circuit layer 50 and n memory layers 11. The memory layers 11 each include a memory cell array 15. The memory cell array 15 includes a plurality of memory cells 10.

The n memory layers 11 are provided over the driver circuit layer 50. Provision of the n memory layers 11 over the driver circuit layer 50 can reduce the area occupied by the memory device 100. Furthermore, memory capacity per unit area can be increased.

In this embodiment and the like, the first memory layer 11 is denoted by a memory layer 11_1, the second memory layer 11 is denoted by a memory layer 11_2, and the third memory layer 11 is denoted by a memory layer 11_3. Furthermore, the k-th memory layer 11 (k is an integer greater than or equal to 1 and less than or equal to n) is denoted by a memory layer 11_k, and the n-th memory layer 11 is denoted by a memory layer 11_n. Note that in this embodiment and the like, the “memory layer 11” is merely stated in some cases when describing a matter related to all the n memory layers 11 or showing a matter common to the n memory layers 11.

### <Structure Example of Driver Circuit Layer 50>

The driver circuit layer 50 includes a PSW 22 (power switch), a PSW 23, and a peripheral circuit 31. The peripheral circuit 31 includes a peripheral circuit 41, a control circuit 32, and a voltage generation circuit 33.

In the memory device 100, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside.

The signal CLK is a clock signal. The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 100. For example, the control circuit performs logical operation on the signal CE, the signal GW, and the signal BW to determine an operation mode (e.g., writing operation or reading operation) of the memory device 100. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47, an output circuit 48, and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting a wiring WWL (write word line) or a wiring RWL (read word line) specified by the row decoder 42. The column driver 45 has a function of writing data to the memory cells 10, a function of reading data from the memory cells 10, a function of retaining the read data, and the like. The column driver 45 has a function of selecting a wiring WBL (write bit line) or a wiring RBL (read bit line) specified by the column decoder 44.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the memory device 100. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 100, a high power supply voltage is VDD and a low power supply voltage is GND (a ground potential). In addition, VHM is a high power supply voltage used to set a word line at a high level and is higher than VDD. The on/off state of the PSW 22 is controlled by the signal PON1, and the on/off state of the PSW 23 is controlled by the signal PON2. The number of power domains to which VDD is supplied is one in the peripheral circuit 31 in FIG. 1B but can be more than one. In that case, a power switch is provided for each power domain.

### <Structure Example of Memory Layer 11>

A structure example of the n memory layers 11 is described. Each of the n memory layers 11 includes the memory cell array 15. The memory cell array 15 includes the plurality of memory cells 10. FIG. 1(B) illustrates an example in which the memory array 15 includes the plurality of memory cells 10 arranged in a matrix of p rows and q columns (each of p and q is an integer greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”.

In FIG. 1B, the memory cell 10 provided in the first row and the first column is referred to as a memory cell 10[1,1], and the memory cell 10 provided in the p-th row and the q-th column is referred to as a memory cell 10[p,q]. The memory cell 10 provided in the i-th row and the j-th column (i is an integer greater than or equal to 1 and less than or equal to p, and j is an integer greater than or equal to 1 and less than or equal to q) is referred to as a memory cell 10[i,j].

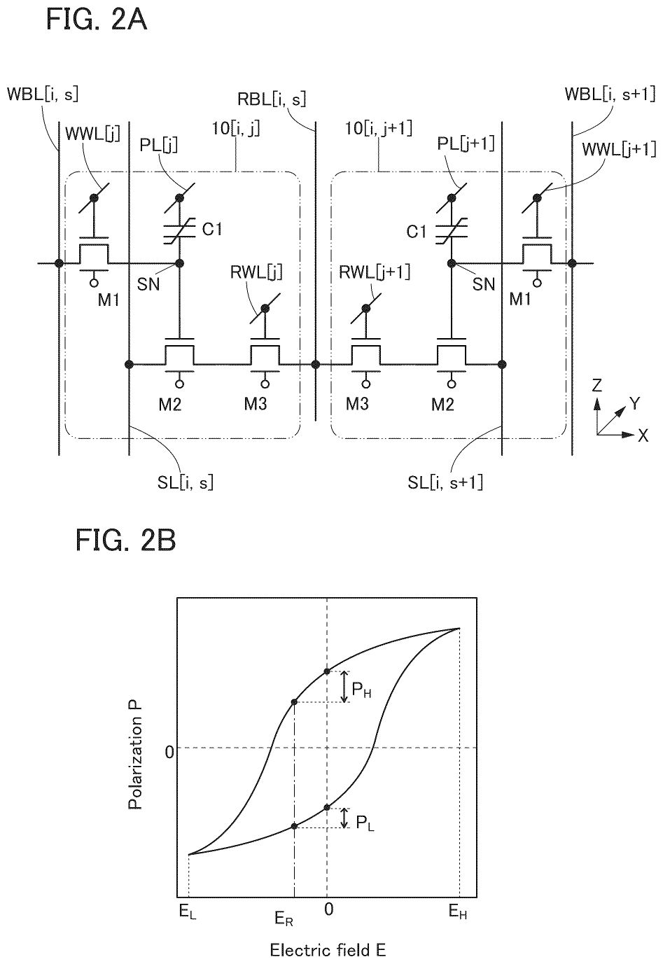

FIG. 2A illustrates a circuit structure example of the memory cell.

The memory cell 10 includes a transistor M1, a transistor M2, a transistor M3, and a capacitor C1. A memory cell composed of three transistor and one capacitor is also referred to as a 3Tr1C memory cell. Thus, the memory cell 10 shown in this embodiment is a 3Tr1C memory cell. Here, a ferroelectric is preferably used as a dielectric of the capacitor C1.

In the memory cell 10[i,j], agate of the transistor M1 is electrically connected to a wiring WWL[j], and one of a source and a drain of the transistor M1 is electrically connected to a wiring WBL[i,s]. The wiring WBL[i,s] is electrically connected to one of the source and the drain of the transistor M1 included in the memory cell 10[i,j] of another stacked memory layer 11. Note that FIG. 2A illustrates a structure example in which the wiring WWL[j] has a function of supplying a gate potential of the transistor M1. The capacitor C1 includes a pair of electrodes. One electrode of the capacitor C1 is electrically connected to a wiring PL[j] and the other electrode thereof is electrically connected to the other of the source and the drain of the transistor M1. Note that FIG. 2A illustrates a structure example in which the wiring PL[j] has a function of supplying a potential to the one electrode of the capacitor C1, for example. A gate of the transistor M2 is electrically connected to the other electrode of the capacitor C1, one of a source and a drain of the transistor M2 is electrically connected to one of a source and a drain of the transistor M3, and the other of the source and the drain of the transistor M2 is electrically connected to a wiring SL[i,s]. The wiring SL[i,s] is electrically connected to the other of the source and the drain of the transistor M2 included in the memory cell 10[i,j] of another stacked memory layer 11. A gate of the transistor M3 is electrically connected to a wiring RWL[j] and the other of the source and the drain of the transistor M3 is electrically connected to a wiring RBL[i,s]. The wiring RBL[i,s] is electrically connected to the other of the source and the drain of the transistor M3 included in the memory cell 10[i,j] of another stacked memory layer 11.

In the memory cell 10[i,j], a region where the other electrode of the capacitor C, the other of the source and the drain of the transistor M1, and the gate of the transistor M2 are electrically connected to one another and have the same potential constantly is referred to as a node SN.

In a memory cell 10[i,j+1], the gate of the transistor M1 is electrically connected to a wiring WWL[j+1], and one of the source and the drain of the transistor M1 is electrically connected to a wiring WBL[i,s+1]. The wiring WBL[i,s+1] is electrically connected to one of the source and the drain of the transistor M1 included in the memory cell 10[i,j+1] of another stacked memory layer 11. Note that FIG. 2A illustrates a structure example in which the wiring WWL[j+1] has a function of supplying agate potential of the transistor M1. The one electrode of the capacitor C1 is electrically connected to a wiring PL[j+1] and the other electrode thereof is electrically connected to the other of the source and the drain of the transistor M1. Note that FIG. 2A illustrates a structure example in which the wiring PL[j+1] has a function of supplying a potential to the one electrode of the capacitor C1, for example. The gate of the transistor M2 is electrically connected to the other electrode of the capacitor C1, one of the source and the drain of the transistor M2 is electrically connected to one of the source and the drain of the transistor M3, and the other of the source and the drain of the transistor M2 is electrically connected to a wiring SL[i,s+1]. The wiring SL[i,s+1] is electrically connected to the other of the source and the drain of the transistor M2 included in the memory cell 10[i,j+1] of another stacked memory layer 11. The gate of the transistor M3 is electrically connected to a wiring RWL[j+1], and the other of the source and the drain of the transistor M3 is electrically connected to the wiring RBL[i,s]. The wiring RBL[i,s] is electrically connected to the other of the source and the drain of the transistor M3 included in the memory cell 10[i,j+1] of another stacked memory layer 11.

From the above, the wiring RBL[i,s] is electrically connected to the other of the source and the drain of the transistor M3 included in the memory cell 10[i,j] and the other of the source and the drain of the transistor M3 included in the memory cell 10[i,j+1]. Thus, the wiring RBL[i,s] functions as a wiring that transmits a signal to the memory cells 10 positioned in adjacent columns. In FIG. 2A, the wiring RBL[i,s] functions as a wiring that transmits a signal to the memory cell 10[i,j] and the memory cell 10[i,j+1]. Although not illustrated, the wiring WBL[i,s] functions as a wiring for transmitting signals to the memory cells 10 positioned in adjacent columns, such as a memory cell 10[i,j−1] and the memory cell 10[i,j] here, and the wiring WBL[i,s+1] functions as a wiring for transmitting signals to the memory cells 10 positioned in adjacent columns, such as the memory cell 10[i,j+1] and a memory cell 10[i,j+2] here. Although not illustrated, the wiring SL[i,s] functions as a wiring for transmitting signals to the memory cells 10 positioned in adjacent columns, such as the memory cell 10[i,j−1] and the memory cell 10[i,j] here, and the wiring SL[i,s+1] functions as a wiring for transmitting signals to the memory cells 10 positioned in adjacent columns, such as the memory cell 10[i,j+1] and the memory cell 10[i,j+2] here.

In the memory cell 10[i,j+1], a region where the other electrode of the capacitor C1, the other of the source and the drain of the transistor M1, and the gate of the transistor M2 are electrically connected to one another and have the same potential constantly is referred to as the node SN.

As illustrated in FIG. 2A, a transistor having a back gate may be used as each of the transistor M1, the transistor M2, and the transistor M3. The gate and the back gate are placed such that a channel formation region of a semiconductor is interposed between the gate and the back gate. The gate and the back gate are formed using conductors. The back gate can function like the gate. By changing the potential of the back gate, the threshold voltage of the transistor can be changed. The potential of the back gate may be the same as the potential of the gate or may be a ground potential or a given potential.

Each of the transistor M1, the transistor M2, and the transistor M3 does not necessarily include a back gate.

In addition, the gate and the back gate are formed using conductors and thus also have a function of preventing an electric field generated outside the transistor from affecting the semiconductor in which a channel is formed (particularly, a function of preventing static electricity). That is, a variation in the electrical characteristics of the transistor due to the influence of an external electric field such as static electricity can be inhibited. Moreover, providing the back gate enables a reduction in the amount of change in the threshold voltage of the transistor before and after a BT (Bias Temperature) test.

For example, the use of a transistor with a back gate for the transistor M1 can reduce the influence of an external electric field, allowing the transistor M1 to be maintained in the stable off state. Thus, data written to the node SN can be retained stably. The back gate stabilizes the operation of the memory cell 10 and increases the reliability of a memory device including the memory cell 10.

Likewise, the use of a transistor with a back gate for the transistor M3 can reduce the influence of an external electric field, allowing the transistor M3 to be maintained in the stable off state. Thus, leakage current between the wiring RBL and the wiring SL can be reduced, resulting in a reduction in the power consumption of the memory device including the memory cell 10.

The semiconductor device of one embodiment of the present invention includes a transistor using an oxide semiconductor, which is a kind of a metal oxide, in a semiconductor layer where a channel is formed (also referred to as an “OS transistor”). An OS transistor has a higher breakdown voltage between its source and drain than a transistor including silicon in a semiconductor layer where a channel is formed (also referred to as a Si transistor). When an OS transistor is used as the transistor M1, the transistor M1 can have sufficient resistance to the reversal polarization voltage of a ferroelectric layer and thus the memory cell 10 can have improved rewrite endurance. In addition, since an OS transistor has high frequency characteristics, the semiconductor device can perform high-speed reading and writing of data.

OS transistors are preferably used for the transistor M1, the transistor M2, and the transistor M3. An oxide semiconductor has a band gap higher than or equal to 2 eV, and thus has extremely low off-state current. Thus, the power consumption of the memory cells 10 can be reduced. Accordingly, the power consumption of the memory device 100 including the memory cells 10 can be reduced.

Note that as semiconductor layers in which the channels of the transistor M1, the transistor M2, and the transistor M3 are formed, a single crystal semiconductor, a polycrystalline semiconductor, a microcrystalline semiconductor, an amorphous semiconductor, or the like is used alone or in combination. As a semiconductor material, silicon or germanium can be used, for example. Alternatively, a compound semiconductor such as silicon germanium, silicon carbide, gallium arsenide, oxide semiconductor, or nitride semiconductor may be used.

A memory cell including an OS transistor can be referred to as an “OS memory”. The memory device 100 including the memory cell can also be referred to as an “OS memory”.

The OS transistor operates stably even in a high-temperature environment and has small variation in characteristics. For example, the off-state current hardly increases even in the high-temperature environment. Specifically, the off-state current hardly increases even at an environmental temperature higher than or equal to room temperature and lower than or equal to 200° C. Furthermore, the on-state current of the OS transistor is unlikely to decrease even in a high-temperature environment. Thus, the OS memory can operate stably and have high reliability even in the high-temperature environment.

Furthermore, an OS transistor has electrical characteristics superior to those of a Si transistor in a high-temperature environment. Specifically, the ratio between on-state current and off-state current is high even at a high temperature higher than or equal to 100° C. and lower than or equal to 200° C., preferably higher than or equal to 125° C. and lower than or equal to 150° C.; hence, favorable switching operation can be performed.

In the memory device of one embodiment of the present invention, a ferroelectric is preferably used as the dielectric of the capacitor C1.

When a ferroelectric is used as the dielectric of the capacitor C1, the amount of electric charges that can be held in the capacitor C1 can be increased as compared with the case where a paraelectric is used as the dielectric. Thus, the memory device of one embodiment of the present invention can retain data for a long time. Accordingly, the frequency of refresh (data rewriting to the cell) can be reduced, leading to a reduction in power consumption of the memory device of one embodiment of the present invention. A capacitor in which a ferroelectric layer is provided between a first electrode and a second electrode can retain data for a long time without a structure for increasing capacity, e.g., a trench structure. Accordingly, a memory device which is easily manufactured can be obtained. A capacitor including a ferroelectric layer is referred to as a ferroelectric capacitor in some cases.

In the capacitor including a ferroelectric layer, when a voltage (electric field) is applied between two electrodes between which the ferroelectric layer is interposed, the polarization direction and the polarization amount of the ferroelectric layer change in accordance with the direction and the amount of the applied voltage. By utilizing a change in the polarization state of the ferroelectric layer, a signal (data) is stored (written) between the two electrodes between which the ferroelectric layer is interposed. After storing (writing) in the capacitor is performed, polarization remains in the ferroelectric layer (remanent polarization) even though the voltage between the two electrodes between which the ferroelectric layer is interposed is set to zero. To renew the polarization, voltage for reversing the polarization (polarization reversal voltage) is applied.

FIG. 2B is a graph showing a polarization magnitude (polarization amount) corresponding to electric fields applied to the ferroelectric layer. The horizontal axis in FIG. 2B represents an electric field E applied to the ferroelectric layer. The vertical axis represents polarization amount P of the ferroelectric layer.

The polarization in the ferroelectric layer increases as the electric field applied to the ferroelectric layer increased. When the electric field applied to the ferroelectric layer is decreased after an electric field EH is applied to the ferroelectric layer, positive electric charges are pulled to one electrode side of the capacitor and negative electric charges are pulled to the other electrode side of the capacitor; thus, positive polarization remains when the electric field becomes 0. The polarization in the ferroelectric layer decreases as the electric field applied to the ferroelectric layer decreases. When the electric field applied to the ferroelectric layer is increased after an electric field E_{L} is applied to the ferroelectric layer, positive electric charges are pulled to the other electrode side of the capacitor C1 and negative electric charges are pulled to the one electrode side of the capacitor; thus, negative polarization remains when the electric field becomes 0. Voltages for applying the electric field EH and the electric field E_{L} to the ferroelectric layer can be referred to as a polarization reversal voltage. When the polarization reversal voltage is applied to the capacitor C1, data can be written to the memory cell 10.

When a voltage that exceeds the polarization reversal voltage is applied to the capacitor C1 in data reading from the memory cell 10, the polarization state of the ferroelectric layer (the polarization direction of the remnant polarization) changes, which requires operation for returning the polarization state to the original state. That is, data refresh is required when data is read from the memory cell 10 by applying a voltage that exceeds the polarization reversal voltage to the capacitor C1.

In one embodiment of the present invention, in data reading from the memory cell 10, operation is performed such that a voltage that does not exceed the polarization reversal voltage is applied to a capacitor 101 so that the polarization state of the ferroelectric layer is returned to the original state even when the electric field is returned to 0. Specifically, in data reading from the memory cell 10, an electric field E_{R} that does not cause polarization reversal in the ferroelectric layer is applied, and the amount of change in polarization (P_{H}, P_{L}) with the electric field E_{R} is used to read data from the memory cell 10. The electric field E_{R} can be an electric field that sets the polarization to zero (a coercive field), for example.

A voltage for applying the electric field E_{R} to the ferroelectric layer can be referred to as a voltage that does not cause polarization reversal. By applying the voltage that does not cause polarization reversal to the capacitor C1, a change in potential corresponding to the amount of change in polarization (P_{H}, P_{L}) is amplified, whereby data can be read from the memory cell 10. Note that although a negative electric field is shown as the electric field ER in FIG. 2B, a positive electric field may be used.

That is, one embodiment of the present invention enables data reading from the memory cell 10 without performing what is called destructive reading, in addition to the advantages of ferroelectric capacitor that data can be retained for a long time. In other words, since the polarization state does not change before and after data reading, data refresh is not required and data can be retained for along time. Thus, a memory device including the memory cell 10 excels in the reliability of read data. Furthermore, the power consumption of the memory device including the memory cell 10 can be reduced. The area of the capacitor can be smaller than that of a capacitor including a paraelectric, for example.

Examples of a material that can have ferroelectricity and can be used for the ferroelectric layer include a material where an element J (here, the element J is zirconium (Zr), silicon (Si), aluminum (Al), gadolinium (Gd), yttrium (Y), lanthanum (La), strontium (Sr), or the like) is added to hafnium oxide, zirconium oxide, HfZrO_{X} (X is a real number greater than 0), or hafnium oxide and a material where an element J2 (here, the element J2 is hafnium (Hf), silicon (Si), aluminum (Al), gadolinium (Gd), yttrium (Y), lanthanum (La), strontium (Sr), or the like) is added to zirconium oxide.

Here, the atomic ratio of a hafnium atom to the element J1 can be set as appropriate. For example, the atomic ratio of a hafnium atom to a zirconium atom may be 1:1 or in the neighborhood thereof. The atomic ratio of a zirconium atom to the element J2 can be set as appropriate; the atomic ratio of a zirconium atom to the element J2 is, for example, 1:1 or in the neighborhood thereof.

Furthermore, as the material that can have ferroelectricity, piezoelectric ceramics having a perovskite structure, such as PbTiO_{X}, barium strontium titanate (BST), strontium titanate, lead zirconate titanate (PZT), strontium bismuth tantalate (SBT), bismuth ferrite (BFO), or barium titanate can also be used. For example, the material that can have ferroelectricity can be a plurality of materials selected from the above-listed materials or can have a stacked-layer structure of a plurality of materials selected from the above-listed materials. Note that hafnium oxide, zirconium oxide, HfZrO_{X}, a material in which the element J1 is added to hafnium oxide, or the like may change its crystal structure (characteristics) according to processes and the like as well as film formation conditions; thus, in this specification and the like, a material that exhibits ferroelectricity is referred to not only as a ferroelectric but also as a material that can have ferroelectricity or a material that has ferroelectricity.

As the material that can have ferroelectricity, scandium aluminum nitride (Al₁₋ₐScₐN_{b} (a is a real number greater than 0 and less than 0.5, and b is 1 or an approximate value thereof, and Al₁₋ₐScₐN_{b} is hereinafter simply referred to as AlScN)), an Al—Ga—Sc nitride, a Ga—Sc nitride, or the like can be used. As the material that can have ferroelectricity, a metal nitride containing an element M1, an element M2, and nitrogen can also be used. Here, the element M1 is one or more selected from aluminum (Al), gallium (Ga), indium (In), and the like. The element M2 is one or more selected from boron (B), scandium (Sc), yttrium (Y), lanthanoids (lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu)), actinoids (15 elements from actinium (Ac) to lawrencium (Lr)), titanium (Ti), zirconium (Zr), hafnium (Hf), vanadium (V), niobium (Nb), tantalum (Ta), chromium (Cr), and the like. Note that the atomic ratio of the element M1 to the element M2 can be set as appropriate. A metal oxide containing the element M1 and nitrogen shows ferroelectricity in some cases even though the metal oxide does not contain the element M2. As the material that can have ferroelectricity, a material in which an element M3 is added to the above metal nitride can be used. Note that the element M3 is one or more selected from magnesium (Mg), calcium (Ca), strontium (Sr), zinc (Zn), cadmium (Cd), and the like. Here, the atomic ratio of the element M1 to the element M2 and the element M3 can be set as appropriate. Since the above metal nitride contains at least a Group 13 element and nitrogen, which is a Group 15 element, the metal nitride is referred to as a ferroelectric of Group 13 to 15, a ferroelectric of a Group 13 nitride, or the like in some cases.

As the material that can have ferroelectricity, a perovskite-type oxynitride such as SrTaO₂N or BaTaO₂N, GaFeO₃ with a K-alumina-type structure, or the like can be used.

The material that can show ferroelectricity can be, for example, a mixture or a compound formed of a plurality of materials selected from the above-listed materials. Alternatively, the material that can have ferroelectricity can have a stacked-layer structure of a plurality of materials selected from the above-listed materials. Note that the above-listed materials are referred to as a material that can have ferroelectricity or a material that has ferroelectricity in some cases.

Among the ferroelectric layers, a hafnium oxide layer or a layer containing hafnium oxide and zirconium oxide is preferable because the layer can have ferroelectricity even when being processed into a thin film of several nanometers. With the ferroelectric layer that can be thin, the memory device combined with a miniaturized transistor can be obtained.

Alternatively, in the case where HfZrO_{X} is used as the material that can have ferroelectricity, it is preferable to deposit HfZrO_{X} by an atomic layer deposition (ALD) method, especially a thermal ALD method. In the case where deposition of the material that can have ferroelectricity is performed by a thermal ALD method, it is suitable to use a material that does not contain a hydrocarbon (also referred to as Hydro Carbon or HC) for a precursor. When the material that can have ferroelectricity contains one or both of hydrogen and carbon, crystallization of the material that can have ferroelectricity might be hindered. Thus, the precursor that does not contain a hydrocarbon is preferably used as described above to reduce the concentration(s) of one or both of hydrogen and carbon in the material that can have ferroelectricity. Examples of the precursor that does not contain a hydrocarbon include a chlorine-based material. In the case where a material containing a hafnium oxide and a zirconium oxide (HfZrO_{X}) is used as the material that can have ferroelectricity, one or both of HfCl₄ and ZrCl₄ are used as the precursor. Since an ALD method is a deposition method in which a precursor and a reactant (e.g., oxidizer) are alternately introduced and the film thickness can be adjusted with the number of repetition times of the cycle, accurate control of the film thickness is possible.

The film deposited by an ALD method is preferably subjected to heat treatment. For heat treatment, an RTA (Rapid Thermal Anneal) apparatus, a resistance heating furnace, or a microwave heating apparatus can be used, for example. It is particularly preferable to use an RTA apparatus because a film having excellent ferroelectricity can be obtained in some cases.

Note that in the case where a film using the material that can have ferroelectricity is deposited, impurities in the film, here, at least one of hydrogen, hydrocarbon, and carbon are thoroughly eliminated, so that a highly purified intrinsic film having ferroelectricity can be formed. Note that the highly purified intrinsic film having ferroelectricity and a highly purified intrinsic oxide semiconductor described in a later embodiment are highly compatible with each other in the manufacturing process. Therefore, a method for manufacturing a memory device with high productivity can be provided.

In the case where HfZrO_{X} is used as the material that can have ferroelectricity, it is preferable to deposit hafnium oxide and zirconium oxide alternately by a thermal ALD method such that the ratio of hafnium oxide to zirconium oxide is 1:1.

In the case where deposition of the material that can show ferroelectricity is performed by a thermal ALD method, H₂O or O₃ can be used as an oxidizer. However, the oxidizer in the thermal ALD method is not limited thereto. For example, the oxidizer in the thermal ALD method may contain any one or more selected from O₂, O₃, N₂O, NO₂, H₂O, and H₂O₂.

In addition, the crystalline structure of the material that can have ferroelectricity is not particularly limited. For example, the material that can show ferroelectricity has any one or more selected from cubic, tetragonal, orthorhombic, and monoclinic crystal structures. In particular, the material that can have ferroelectricity preferably has an orthorhombic crystal structure because the material exhibits ferroelectricity. Alternatively, the material that can have ferroelectricity may have a composite structure of an amorphous structure and a crystal structure.

The wiring WBL is supplied with a signal (data signal) corresponding to data written to the memory cell 10. The wiring WBL is referred to as a write bit line in some cases. The wiring WBL can be a wiring used in common with other wirings, for example, the wiring RBL.

The wiring WWL is supplied with a signal (selection signal) for writing data to the memory cell 10. The wiring WWL is referred to as a write word line in some cases.

The wiring PL is supplied with a signal (control signal) for writing data to the memory cell 10 and a signal (control signal) for reading data from the memory cell 10. The wiring PL has a function of controlling the polarization state of a layer including the ferroelectric, which is included in the capacitor C1, and is sometimes referred to as a polarization control line.

The wiring SL is supplied with a constant potential used for reading data from the memory cell 10. The wiring SL has a function of making current flow between the wiring SL and the wiring RBL in accordance with data stored in the memory cell 10, and is referred to as a source line in some cases.

The wiring RBL is supplied with a signal corresponding to data read from the memory cell 10. The wiring RBL is referred to as a read bit line in some cases. The wiring RBL can be a wiring used in common with other wirings, for example, the wiring WBL.

Each of the transistors in the memory cell 10 illustrated in FIG. 2A is described as an n-channel transistor. For example, in the case where the transistor M1 is an n-channel transistor, the transistor M1 can be brought into an on state (on) when the wiring WWL is set to have a high potential (also referred to as an H level potential or an H level). Furthermore, the transistor M1 can be brought into an off state (off) when the wiring WWL is set to have a low potential (also referred to as an L level potential or an L level). The same applies to the transistor M3.

Data writing to the memory cell 10 is performed in accordance with the direction of an electric field applied to the layer including the ferroelectric, which is included in the capacitor C1, owing to the potential of the node SN and the potential of the wiring PL. Although the details will be described later, the polarization reversal voltage is applied to the capacitor C1 by the written data signal. The ferroelectric layer included in the capacitor C1 can have different polarization states depending on the data signal. The capacitance value of the capacitor C1 can differ depending on the polarization states. The variations in the polarization state and the capacitance value of the capacitor C1 is maintained even when the electric field applied to the capacitor C1 is 0.

Data reading from the memory cell 10 is performed by utilizing capacitive coupling of the capacitor C1 that occurs when the potential of the wiring PL is changed. The potential of the wiring PL is set such that the voltage applied to the capacitor C1 is a voltage that does not cause polarization reversal of the ferroelectric layer. When the node SN is in an electrically floating state and the potential of the wiring PL is changed, capacitive coupling occurs in the capacitor C1. Accordingly, the potential of the node SN changes in accordance with the change in the potential of the wiring PL. The change in the potential of the node SN is different depending on the state of the capacitance value of the capacitor C1. Thus, the potential of the gate of the transistor M2 can be made different depending on the stored data. Different potentials of the gate of the transistor result in different amounts of current flowing between the source and the drain of the transistor M2. Data can be read from the memory cell 10 owing to the difference in the amount of current.

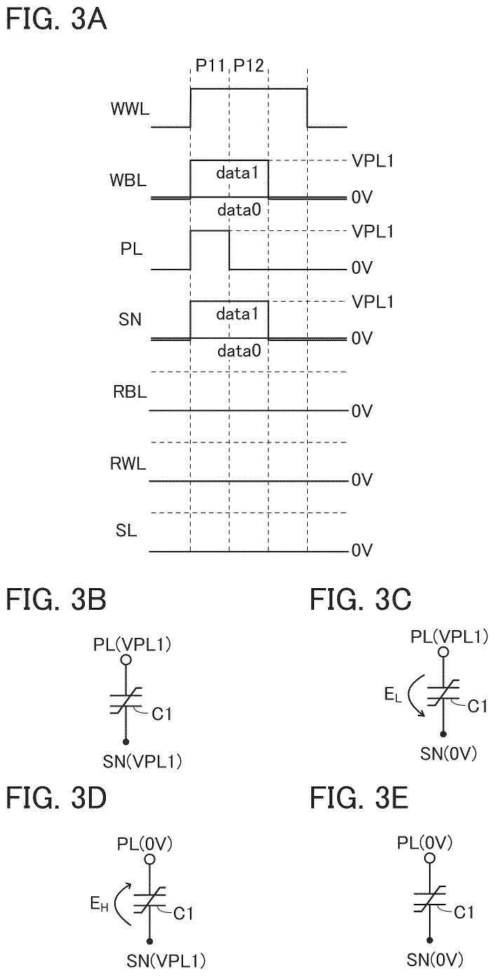

FIG. 3A is a timing chart for illustrating a data writing operation of the memory cell 10 illustrated in FIG. 2A. FIG. 3A shows signals or potentials of the wiring WWL, the wiring WBL, the wiring PL, the node SN, the wiring RBL, the wiring RWL, and the wiring SL in the memory cell 10. In FIG. 3A, “data1” and “data0” are shown as data to be written to the memory cell 10. “data1” is shown as an H-level signal, and “data0” is shown an L-level signal.

In Period P11 shown in FIG. 3A, the wiring WWL is set at the H level. The wiring WBL is supplied with a signal corresponding to data data1 or data0 to be written to the memory cell 10, and a potential corresponding to the signal is supplied to the node SN. The wiring PL is set at the H level. The wiring RBL, the wiring RWL, and the wiring SL are set at the L level.

A potential VPL1 and a potential 0 V denote respectively a H-level signal and a L-level signal supplied to the wiring WBL, the wiring PL, and the node SN. The reversal polarization voltage is applied to the ferroelectric layer of the capacitor C1 by applying the potential VPL1 to the one electrode of the capacitor C1 and the potential 0 V to the other electrode. The potential VPL1 is preferably higher than or equal to 2.5 V.

In the case where a voltage that exceeds the reversal polarization voltage is applied to the capacitor C1 by supplying the potential VPL1, the transistor M1 to the transistor M3 are preferably transistors having excellent resistance to high voltages (breakdown voltage). When the transistor M1 to the transistor M3 are OS transistors having higher breakdown voltage than the Si transistors, the memory cell 10 can have improved rewrite endurance.

In Period P11, when the wiring PL is at the H level and the node SN is at the H level, the potentials illustrated in FIG. 3B are applied to the electrodes of the capacitor C1. Since the electrodes at both ends of the capacitor C1 are each at the potential VPL1 as illustrated in FIG. 3B, a voltage that exceeds the reversal polarization voltage is not applied, preventing generation of an electric field in the ferroelectric layer. Meanwhile, in Period P11, when the wiring PL is at the H level and the node SN is at the L level, the potentials illustrated in FIG. 3C are applied to the electrodes of the capacitor C1. As illustrated in FIG. 3C, a voltage VPL1 that serves as the reversal polarization voltage is applied to the electrode of the capacitor C1, so that the electric field E_{L} is generated in the ferroelectric layer. Thus, the polarization state corresponding to data0 is written to the capacitor C1.

In Period P12 illustrated in FIG. 3A, the wiring WWL is set at the H level subsequently to Period P11. A signal corresponding to data data1 or data0 to be written to the memory cell 10 is supplied to the wiring WBL subsequently to Period P11, and a potential corresponding to the signal is supplied to the node SN. The wiring PL is set at the L level. The wiring RBL, the wiring RWL, and the wiring SL are set at the L level.

In Period P12, when the wiring PL is at the L level and the node SN is at the H level, the potentials illustrated in FIG. 3D are applied to the electrodes of the capacitor C1. As illustrated in FIG. 3D, an electric field in a direction opposite to that in Period P11 is applied to the pair of electrodes of the capacitor C1 and the voltage VPL1 that serves as the reversal polarization voltage is applied to the electrode of the capacitor C1, whereby the electric field EH is generated in the ferroelectric layer. Thus, the polarization state corresponding to data1 is written to the capacitor C1. Meanwhile, in Period P12, when the wiring PL is at the L level and the node SN is at the L level, the potentials of the electrodes of the capacitor C1 are equal to the potential 0 V as illustrated in FIG. 3E; hence, a voltage that exceeds the reversal polarization voltage is not applied and an electric field is not generated in the ferroelectric layer.

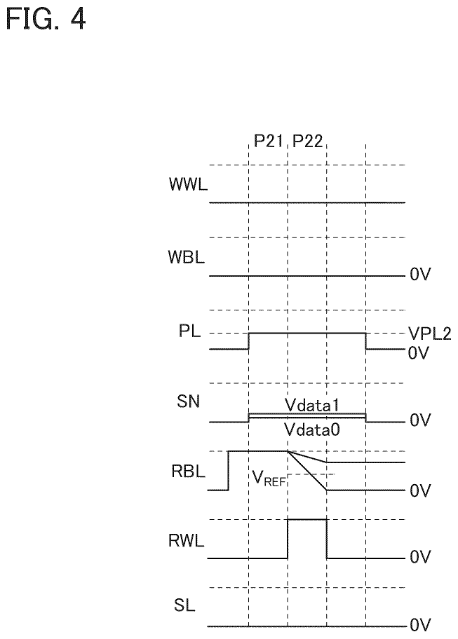

FIG. 4 is a timing chart for illustrating a data reading operation of the memory cell 10 illustrated in FIG. 2. FIG. 4 shows signals or potentials of the wiring WWL, the wiring WBL, the wiring PL, the node SN, the wiring RBL, the wiring RWL, and the wiring SL in the memory cell 10. In FIG. 4, “data1” and “data0” are shown as data read from the memory cell 10. In FIG. 4, “data1” and “data0” each correspond to data stored as the polarization state of the ferroelectric layer of the capacitor C1 in the data writing operation.

In Period P21 shown in FIG. 4, the wiring WWL is set at the L level. The node SN is in an electrically floating state. The wiring PL is set at a potential VPL2. The wiring WBL, the wiring RWL, and the wiring SL are set at the L level. In a period before Period P21, the wiring RBL is precharged to a potential at which a potential changes in accordance with current flowing through the transistor M2 and the transistor M3. For example, the wiring RBL is precharged to a potential lower than the potential VPL1.

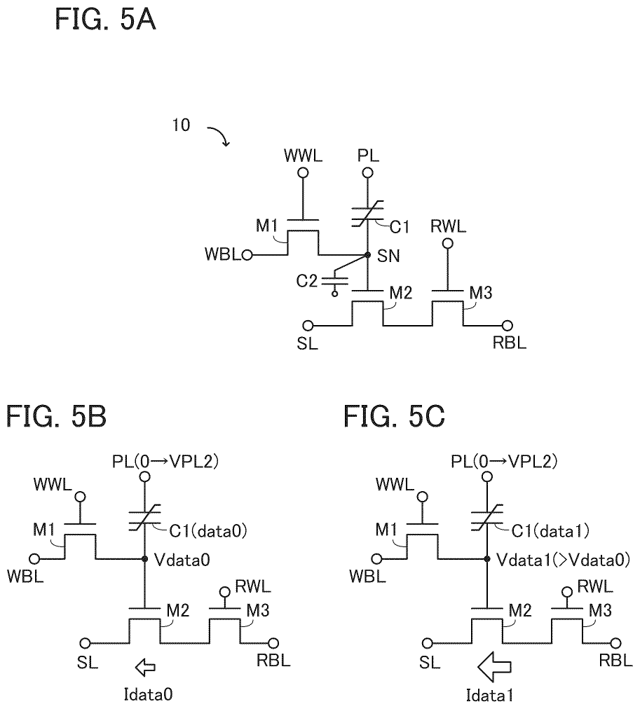

As illustrated in FIG. 5A, the node SN in the memory cell 10 includes a capacitor C2 that is parasitic capacitance such as the gate capacitance of the transistor M2. When the node SN is in an electrically floating state and the potential of the one electrode of the capacitor C1 is changed, the potential of the node SN may change due to capacitive coupling of the capacitor C1 and the capacitor C2.

The amount of change in a potential V_{SN} of the node SN, ΔV_{SN}, is determined by a capacitance value C_{FE} of the capacitor C1, a capacitance value C_{S} of the capacitor C2, and the amount of change in a voltage VPL2 corresponding to the voltage of the capacitor C1, ΔVPL2, and can be expressed by Formula (1).

$$[ Formula 1 ]$$

$$Δ {V}_{SN} = \frac{{C}_{FE}}{( {C}_{FE} + {C}_{S} )} \times Δ VPL 2 \qquad ( 1 )$$

The capacitance value C_{FE} of the capacitor C1 is determined by the polarization state of the ferroelectric layer included in the capacitor C1. The polarization state differs depending on the written data “data1” or “data0”. Thus, the potential V_{SN} of the node SN can be changed by the written data “data1” or “data0”. The capacitance value C_{S} of the parasitic capacitance (the capacitor C2) of the node SN is smaller than the capacitance value C_{FE} of the capacitor C1 including the ferroelectric layer. A difference in potential due to a difference in capacitance value depending on the polarization state of the capacitor C1 appears as Vdata0 or Vdata1 in the potential V_{SN} of the node SN.

In Period P22 shown in FIG. 4, the wiring RWL is set at the H level. Electrical continuity is established between the source and the drain of the transistor M3. Current corresponding to the potential of the node SN flows through the transistor M2.

When the wiring PL is set at the voltage VPL2, the potential of the node SN can have two states, the potential Vdata0 or the potential Vdata1(>Vdata0) as illustrated in FIG. 5B and FIG. 5C. Current Idata0 or Idata1(>Idata0) corresponding to the potential Vdata0 or Vdata1 flows to the transistor M2. When the current Idata0 or Idata1 flows, the potential of the precharged wiring RBL changes. The potential of the wiring RBL after the change is determined in accordance with the amount of current flowing through the transistor M2 (Idata0 or Idata1). By comparing the magnitude relation between the potential of the wiring RBL after the change and a reference voltage V_{REF}, whether the written data is “data1” or “data0” is determined and data can be read from the memory cell 10. In FIG. 4, when the current Idata0 flows to the transistor M2, for example, the potential of the wiring RBL becomes higher than the reference voltage V_{REF}, and when the current Idata1 flows to the transistor M2, for example, the potential of the wiring RBL becomes lower than the reference voltage V_{REF} after a predetermined time passes.

Note that the potential of the wiring RBL to be precharged is preferably lower than the potential VPL1. With this structure, a change in the potential of the wiring RBL can be small. Thus, even when a transistor electrically connected to the wiring RBL and included in a circuit is a Si transistor or the like with minute size and has a low breakdown voltage, the circuit can operate without problems.

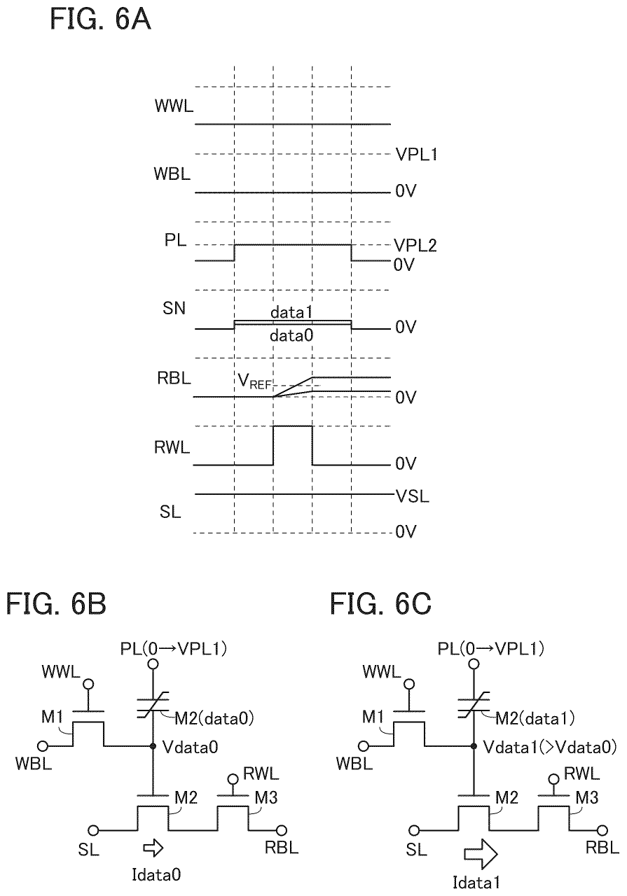

Note that the operation of reading data from the memory cell 10 in FIG. 2A can have a different structure. For example, the operation may be performed as in the timing chart in FIG. 6A. Unlike in FIG. 4, current corresponding to the potential of the node SN flows in the state where the potential of the wiring SL is increased and the wiring RBL is precharged to 0 V in FIG. 6A. That is, as illustrated in FIG. 6B and FIG. 6C, the current Idata0 or Idata1(>Idata0) corresponding to the potential Vdata0 or Vdata1 flows from the wiring SL to the wiring RBL in the transistor M2. By comparing the magnitude relation between the potential of the wiring RBL and the reference voltage V_{REF}, data can be read from the memory cell 10. In FIG. 6A, when the current Idata0 flows to the transistor M2, for example, the potential of the wiring RBL becomes lower than the reference voltage V_{REF}, and when the current Idata1 flows to the transistor M2, for example, the potential of the wiring RBL becomes higher than the reference voltage V_{REF} after a predetermined time passes.

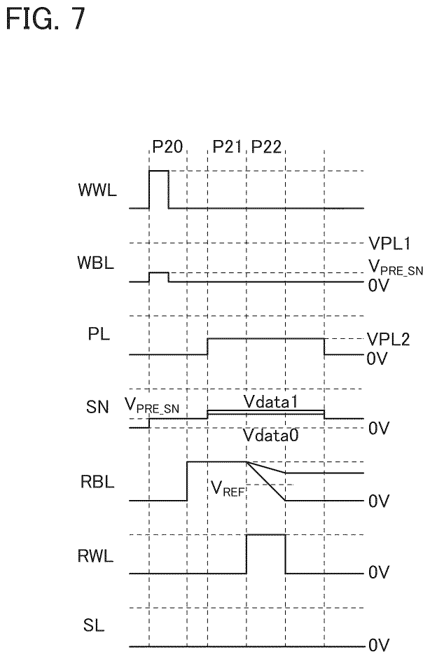

The operation of reading data from the memory cell 10 in FIG. 2A can be performed by another operation method. For example, the operation may be performed as in the timing chart in FIG. 7.

FIG. 7 corresponds to an operation method in which operation of setting the potential of the node SN is added to the operation in FIG. 4. In Period P20 in FIG. 7, the potential of the wiring WBL is set to a desired potential V_{PRE_SN}, and the wiring WWL is set at the H level. The potential of the node SN becomes the potential V_{PRE_SN}. After that, the wiring WWL is set at the L level so that the node SN is brought into an electrically floating state. In this manner, the potential of the node SN, which varies due to the change in the potential of the wiring PL in Period P21, can be easily set to current where the transistor M2 supplies current.

This embodiment can be combined with the other embodiments as appropriate.

### Embodiment 2

In this embodiment, a semiconductor device of one embodiment of the present invention is described with reference to drawings.

One embodiment of the present invention relates to a semiconductor device in which a memory layer is provided over a substrate. The memory layer includes a first transistor, a second transistor, a third transistor, and a capacitor, which can form a memory cell. The semiconductor device of one embodiment of the present invention includes the memory cell and thus has a function of storing data. Therefore, the semiconductor device of one embodiment of the present invention can be referred to as a memory device.

In the semiconductor device of one embodiment of the present invention, a plurality of memory layers each having the above structure are stacked. That is, the plurality of memory layers each having the above structure are provided in the direction perpendicular to a substrate surface, for example. Thus, without an increase in the area occupied by memory cells, the semiconductor device can have larger memory capacity than a semiconductor device including one memory layer. This can reduce the area occupied per bit, enabling the semiconductor device to have a small size and a large memory capacity. In an OS transistor, a semiconductor layer where a channel is formed can be formed by a thin film method such as a sputtering method. An OS transistor can be formed at a low temperature, e.g., a temperature lower than or equal to 750° C. Thus, a plurality of layers including OS transistors can be stacked. OS transistors can be suitably used for a plurality of memory layers that are stacked.

An OS transistor can freely be placed by being stacked over a circuit using a Si transistor or the like, which facilitates integration. As the silicon, amorphous silicon (referred to as hydrogenated amorphous silicon in some cases), microcrystalline silicon, polycrystalline silicon, single crystal silicon, or the like can be used, for example. Furthermore, an OS transistor can be manufactured with a manufacturing apparatus similar to that for a Si transistor and thus can be manufactured at low cost.

In a gain-cell memory cell, at least two transistors are required for one memory cell, which makes it difficult to increase the number of memory cells per unit area. However, when an OS transistor is used as a transistor included in the memory cell 10, a plurality of memory cell arrays 15 can be stacked. That is, the amount of data that can be stored per unit area can be increased.

In the case where a plurality of memory layers are stacked, for example, a write bit line and a read bit line can be provided in a direction perpendicular to the substrate surface. For example, in the case where a semiconductor device including n memory layers (n is an integer greater than or equal to 2) is formed, an opening is provided so as to penetrate the n memory layers and a conductor is formed inside the opening, whereby the write bit line and the read bit line can be formed. Here, in the semiconductor device of one embodiment of the present invention, a conductor including a region functioning as the write bit line is provided so as to include a region in contact with the top surface and a side surface of a first conductor.

### <Structure Example of Semiconductor Device>

Structure examples of a semiconductor device of one embodiment of the present invention will be described below.

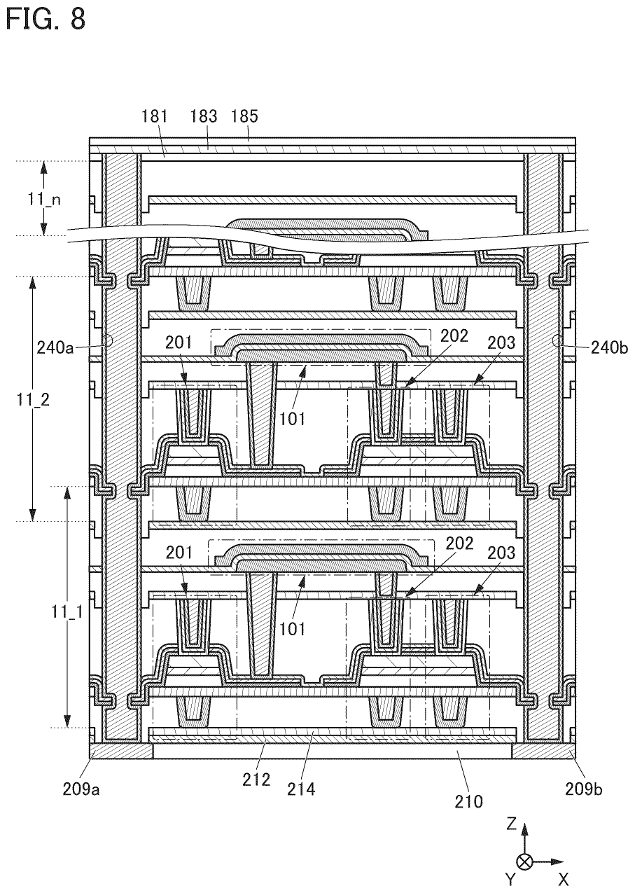

FIG. 8 is a cross-sectional view illustrating a structure example of the semiconductor device of one embodiment of the present invention. The semiconductor device illustrated in FIG. 8 can be used for the circuit structure of the memory cell described in the above embodiment.

The semiconductor device illustrated in FIG. 8 includes an insulator 210 over a substrate (not illustrated); a conductor 209a and a conductor 209b embedded in the insulator 210; an insulator 212 over the insulator 210; an insulator 214 over the insulator 212; the n memory layers 11 over the insulator 214; a conductor 240a that is provided to penetrate the n layers and extend in the Z direction (the Z direction is described later) and is electrically connected to the conductor 209a; a conductor 240b electrically connected to the conductor 209b; an insulator 181 over the memory layer 11_n; an insulator 183 over the insulator 181, the conductor 240a, and the conductor 240b; and an insulator 185 over the insulator 183. Note that components of the semiconductor device of this embodiment may each have either a single-layer structure or a stacked-layer structure.

In the following description of matters common to components distinguished from each other using letters of the alphabet, reference numerals without the letters of the alphabet are sometimes used. For example, in the case where matters common to the conductor 209a and the conductor 209b are described, the term “conductor 209” is used in some cases.

The memory layer 11_1 to the memory layer 11_n are each provided with a memory cell array including a plurality of memory cells. The memory cells each include a transistor 201, a transistor 202, a transistor 203, and the capacitor 101. The conductor 240a includes a region functioning as the write bit line, and the conductor 240b includes a region functioning as the read bit line. The transistor 201, the transistor 202, the transistor 203, and the capacitor 101 can correspond to the transistor M1, the transistor M2, the transistor M3, and the capacitor C1 included in the memory cell 10 described in the above embodiment. The conductor 240a and the conductor 240b can correspond to the wiring WBL and the wiring RBL, respectively.

In this specification and the like, a direction parallel to a channel length direction of a transistor illustrated is referred to as an X direction, and a direction parallel to a channel width direction of a transistor illustrated is referred to as a Y direction. The X direction and the Y direction can be perpendicular to each other. Furthermore, a direction perpendicular to both the X direction and the Y direction, i.e., a direction perpendicular to the XY plane, is referred to as a Z direction. The X direction and the Y direction can each be a direction parallel to the substrate surface, and the Z direction can be a direction perpendicular to the substrate surface, for example.

The conductor 209a and the conductor 209b each function as a wiring, an electrode, a terminal, or part of a circuit element such as a switch, a transistor, a capacitor, an inductor, a resistor, or a diode.

FIG. 8 illustrates, among the n memory layers, the memory layer 11_1 that is the lowest layer, the memory layer 11_2 over the memory layer 11_1, and the memory layer 11_n that is the uppermost layer.

The conductor 209a and the conductor 209b are electrically connected to driver circuits for driving the memory cells provided in the memory layers 11. The driver circuits are provided below the conductor 209a and the conductor 209b. Increasing the number of stacked memory layers 11 (the value of n) can increase the memory capacity of the memory device without an increase in the area occupied by the memory cells. Accordingly, the occupation area per bit is reduced, so that the semiconductor device can have a small size and large memory capacity.

The transistor 201, the transistor 202, and the transistor 203 are provided over the insulator 214. Here, the transistor 202 and the transistor 203 share some layers. The capacitor 101 is provided above the transistor 201 to the transistor 203.

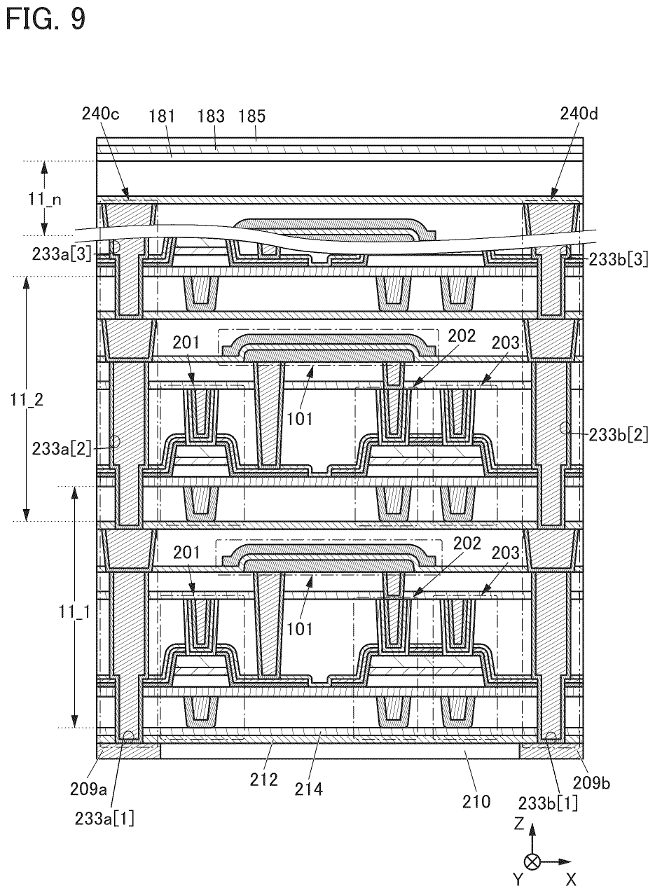

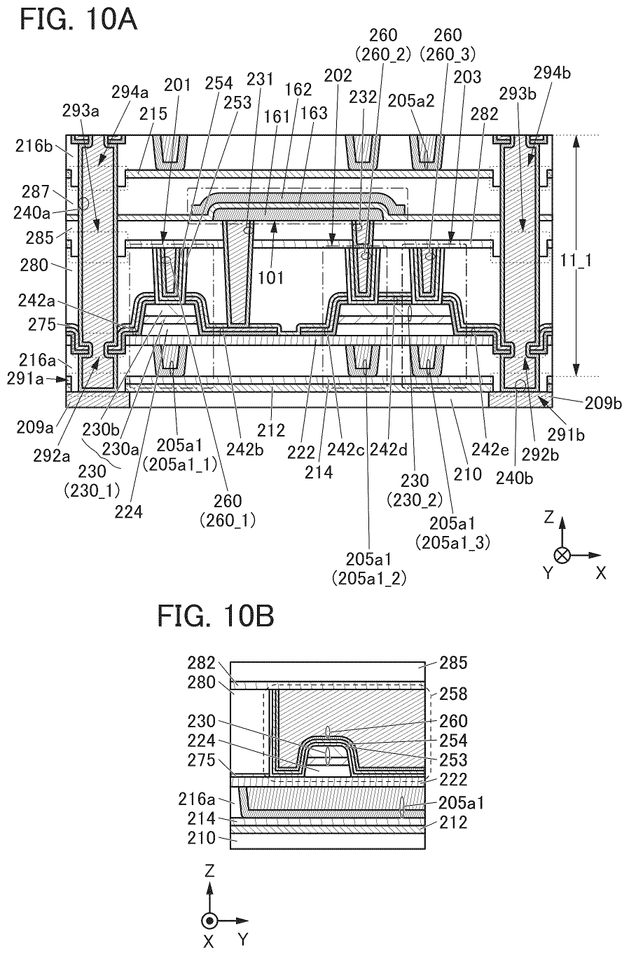

FIG. 9 illustrates an example in which a connection electrode 240c and a connection electrode 240d are provided instead of the conductor 240a and the conductor 240b. The memory layer 11 includes a conductor 233a electrically connected to a conductor 242a (described in detail in FIG. 10) included in the transistor 201, and a conductor 233b electrically connected to a conductor 242e (described in detail in FIG. 10) included in the transistor 203. The conductor 233a and the conductor 233b included in the memory layer 11_k, which is the k-th memory layer 11 (k is an integer greater than or equal to 1 and less than or equal to n), are denoted by a conductor 233a[k] and a conductor 233b[k], respectively. The connection electrode 240c includes a conductor 233a[1] to a conductor 233a[n] (not illustrated), which are electrically connected to each other. The connection electrode 240d includes a conductor 233b[1] to a conductor 233b[n] (not illustrated), which are electrically connected to each other.

FIG. 10A is a cross-sectional view illustrating a structure example of the conductor 209a, the conductor 209b, the insulator 210, the insulator 212, the insulator 214, and the memory layer 11_1. As illustrated in FIG. 10A, an insulator 282 is provided over the transistor 201 to the transistor 203, and an insulator 285 is provided over the insulator 282.

The transistor 201, the transistor 202, and the transistor 203 each include a conductor 205a1 over the insulator 214, an insulator 222 over the conductor 205a1, an insulator 224 over the insulator 222, a metal oxide 230 (a metal oxide 230a and a metal oxide 230b) over the insulator 224, a conductor 242 covering part of a side surface of the insulator 224 and part of the top surface and part of a side surface of the metal oxide 230, an insulator 253 over the metal oxide 230, an insulator 254 over the insulator 253, and a conductor 260 over the insulator 254. Here, the transistor 201 includes the conductor 242a and a conductor 242b as the conductor 242, the transistor 202 includes a conductor 242c and a conductor 242d as the conductor 242, and the transistor 203 includes the conductor 242d and the conductor 242e as the conductor 242. The transistor 202 and the transistor 203 share the metal oxide 230 and the conductor 242d. In FIG. 10 and the like, the conductors 205a1 included in the transistor 201, the transistor 202, and the transistor 203 are denoted by as a conductor 205a1_1, a conductor 205a1_2, and a conductor 205a1_3, respectively. The conductors 260 included in the transistor 201, the transistor 202, and the transistor 203 are denoted by a conductor 260_1, a conductor 260_2, and a conductor 260_3, respectively. The metal oxide 230 included in the transistor 201 is denoted by 230_1, and the metal oxide 230 shared by the transistor 202 and the transistor 202 is denoted by 230_2. The insulator 222 includes a region interposed between the conductor 205a1 and the metal oxide 230 of the transistor 201 and overlapping with the conductor 260 of the transistor 201, a region interposed between the conductor 205a1 and the metal oxide 230 of the transistor 202 and overlapping with the conductor 260 of the transistor 202, and a region interposed between the conductor 205a1 and the metal oxide 230 of the transistor 203 and overlapping with the conductor 260 of the transistor 203. In the structure illustrated in FIG. 10A, the conductor 205a1 preferably includes a region in contact with the bottom surface of the insulator 222.

An insulator 216a provided with an opening is provided over the insulator 214, and the conductor 205a1 is embedded in the opening. The insulator 222 is provided over the conductor 205a1 and the insulator 216a. An insulator 275 is provided over the conductor 242a to the conductor 242e, and an insulator 280 is provided over the insulator 275. The insulator 253, the insulator 254, and the conductor 260 are embedded in an opening provided in the insulator 280 and the insulator 275. The insulator 282 is provided over the insulator 280 and the conductor 260. The conductor 205a1 can include a region in contact with a side surface of the insulator 216a. The insulator 253 can include a region in contact with at least parts of a side surface of the conductor 242, a side surface of the insulator 275, and a side surface of the insulator 280.

The metal oxide 230 includes a region functioning as a channel formation region of the transistor 201, the transistor 202, or the transistor 203. Note that for the transistor 201, the transistor 202, and the transistor 203, a semiconductor such as single crystal silicon, polycrystalline silicon, or amorphous silicon may be used instead of the metal oxide 230; for example, low-temperature polysilicon (LTPS) may be used.

The conductor 242a includes a region functioning as one of a source electrode and a drain electrode of the transistor 201. The conductor 242b includes a region functioning as the other of the source electrode and the drain electrode of the transistor 201. The conductor 242c includes a region functioning as one of a source electrode and a drain electrode of the transistor 202. The conductor 242d includes a region functioning as the other of the source electrode and the drain electrode of the transistor 202 and as one of a source electrode and a drain electrode of the transistor 203. The conductor 242e includes a region functioning as the other of the source electrode and the drain electrode of the transistor 203.

The conductor 260 includes a region functioning as a first gate electrode of the transistor 201, the transistor 202, or the transistor 203. The insulator 253 and the insulator 254 each include a region functioning as a first gate insulator of the transistor 201, the transistor 202, or the transistor 203.

The conductor 205a1 includes a region functioning as a second gate electrode of the transistor 201, the transistor 202, or the transistor 203. The insulator 222 includes a region functioning as a second gate insulator of the transistor 201, a region functioning as a second gate insulator of the transistor 202, and a region functioning as a second gate insulator of the transistor 203. The insulator 224 includes a region functioning as the second gate insulator of the transistor 201, the transistor 202, or the transistor 203.

In this specification and the like, the first gate electrode can be referred to as a front gate electrode or simply as a gate electrode, and the second gate electrode can be referred to as a back gate electrode. Note that the first gate electrode may be referred to as a back gate electrode, and the second gate electrode may be referred to as a front gate electrode or simply as a gate electrode.

The transistor 202 and the transistor 203 are adjacent to each other and share the metal oxide 230 and the conductor 242d as described above. Thus, the two transistors (the transistor 202 and the transistor 203) can be formed in an area smaller than the area of two transistors (e.g., an area of 1.5 transistors). This enables the transistors to be arranged at high density as compared with the case where the transistor 202 and the transistor 203 do not share the metal oxide 230 and the conductor 242d; hence, high integration in the semiconductor device can be achieved.

The conductor 242d is placed in a region between the conductor 260 included in the transistor 202 and the conductor 260 included in the transistor 203. Thus, an n-type region (low-resistance region) can be formed in a region of the metal oxide 230 that overlaps with the conductor 242d. Specifically, the n-type region can be formed in a region of the metal oxide 230b that overlaps with the conductor 242d. Moreover, current can flow between the transistor 202 and the transistor 203 through the conductor 242d. Thus, the resistance component between the transistor 202 and the transistor 203 can be significantly reduced as compared with a structure in which two Si transistors are connected in series.

Note that the conductor 242d covers part of the side surface of the metal oxide 230. For example, although not illustrated, the conductor 242d covers the side surface of the metal oxide 230 in a cross section of the transistor 202 including the conductor 242d in the channel width direction.

The insulator 285 is provided over the insulator 282. An opening reaching the conductor 242b is provided in the insulator 280, the insulator 282, and the insulator 285, and a conductor 231 is embedded in the opening. An opening reaching the conductor 260 included in the transistor 202 is provided in the insulator 282 and the insulator 285, and a conductor 232 is provided in the opening.

The capacitor 101 includes a conductor 161 over the insulator 285, the conductor 231, and the conductor 232, an insulator 163 over the conductor 161, and a conductor 162 over the insulator 163.

The insulator 163 includes a region interposed between the conductor 161 and the conductor 162.

The conductor 161 includes a region functioning as one electrode (also referred to as a lower electrode) of the capacitor 101. The insulator 163 includes a region functioning as a dielectric of the capacitor 101. The conductor 162 includes a region functioning as the other electrode (also referred to as an upper electrode) of the capacitor 101. The capacitor 101 forms a MIM capacitor.

The conductor 242b and the conductor 161 are electrically connected to each other through the conductor 231. The conductor 260 included in the transistor 202 and the conductor 161 are electrically connected to each other through the conductor 232. In this manner, the conductor 242b including the region functioning as the other of the source electrode and the drain electrode of the transistor 201 is electrically connected to the conductor 260 including the region functioning as the gate electrode of the transistor 202 through the conductor 231, the conductor 161, and the conductor 232.

An insulator 287 is provided over the conductor 162 and the insulator 163. An insulator 215 is provided over the insulator 287. An insulator 216b provided with an opening is provided over the insulator 215, and a conductor 205a2 is embedded in the opening.

Hereinafter, in the case where matters common to the conductor 205a1 and the conductor 205a2 are described, the term “conductor 205a” is used in some cases.

The conductor 242a, the conductor 242b, the conductor 242c, and the conductor 242e extend beyond the metal oxide 230 functioning as a semiconductor layer and cover parts of the top surface and the side surface of the metal oxide 230. Thus, the conductor 242a, the conductor 242b, the conductor 242c, and the conductor 242e also function as wirings. The conductor 240a including the region functioning as the write bit line is provided to include a region in contact with parts of the top surface, a side surface, and the bottom surface of the conductor 242a, for example. The conductor 240b including the region functioning as the read bit line is provided to include a region in contact with parts of the top surface, a side surface, and the bottom surface of the conductor 242e. Note that the conductor 242d can also function as a wiring. Another wiring can also function as a wiring in some cases.

When the conductor 240a functioning as the write bit line includes the region in contact with the parts of the top surface, the side surface, and the bottom surface of the conductor 242a, a connection electrode does not need to be provided separately between the write bit line and the conductor 242a. When the conductor 240b functioning as the read bit line includes the region in contact with the parts of top surface, the side surface, and the bottom surface of the conductor 242e, a connection electrode does not need to be provided separately between the read bit line and the conductor 242e. This can reduce the area occupied by the memory cell array. In addition, the integration degree of the memory cells can be increased and the memory capacity can be increased. Note that the conductor 240a includes a region in contact with at least one or more, preferably two or more of the top surface, the side surface, and the bottom surface of the conductor 242a, and the conductor 240b includes a region in contact with one or more, preferably two or more of the top surface, the side surface, and the bottom surface of the conductor 242e. When the conductor 240a is in contact with the plurality of surfaces of the conductor 242a, the contact resistance between the conductor 240a and the conductor 242a can be reduced, and when the conductor 240b is in contact with the plurality of surfaces of the conductor 242e, the contact resistance between the conductor 240b and the conductor 242e can be reduced.

Here, an opening 291a including a region overlapping with the conductor 209a and an opening 291b including a region overlapping with the conductor 209b are provided in the insulator 212 and the insulator 214. An opening 292a including a region overlapping with the conductor 209a and the opening 291a and an opening 292b including a region overlapping with the conductor 209b and the opening 291b are provided in the insulator 222. An opening 293a including a region overlapping with the conductor 209a, the opening 291a, and the opening 292a and an opening 293b including a region overlapping with the conductor 209b, the opening 291b, and the opening 292b are provided in the insulator 282. An opening 294a including a region overlapping with the conductor 209a, the opening 291a, the opening 292a, and the opening 293a and an opening 294b including a region overlapping with the conductor 209b, the opening 291b, the opening 292b, and the opening 293b are provided in the insulator 215. The conductor 240a is provided in the opening 291a to the opening 294a, and the conductor 240a is provided in the opening 291b to the opening 294b. Note that the opening 291a is not necessarily provided in the insulator 212.

In each of the opening 291a and the opening 291b, the insulator 216a covers a side surface of the insulator 212 and a side surface of the insulator 214. The conductor 242a covers a side surface of the insulator 222 in the opening 292a, and the conductor 242b covers a side surface of the insulator 222 in the opening 292b. In each of the opening 293a and the opening 293b, the insulator 285 covers a side surface of the insulator 282. In each of the opening 294a and the opening 294b, the insulator 216b covers a side surface of the insulator 215.

Accordingly, the insulator 216a can be regarded as being provided to cover parts of the top surface and the side surfaces of the insulator 214. In addition, the conductor 242a and the conductor 242e can be regarded as being provided to cover parts of the top surface and the side surfaces of the insulator 222. Moreover, the insulator 285 can be regarded as being provided to cover parts of the top surface and the side surfaces of the insulator 282, and the insulator 216b can be regarded as being provided to cover parts of the top surface and the side surfaces of the insulator 215.

In the semiconductor device of one embodiment of the present invention having the above structure, the conductor 240a and the conductor 240b are each provided to include regions in contact with at least parts of the side surface of the insulator 212, the side surface of the insulator 216a, the side surface of the insulator 275, a side surface of the insulator 285, a side surface of the insulator 287, and a side surface of the insulator 216b. As described above, the conductor 240a and the conductor 240b are provided to include the region in contact with a side surface of the conductor 242a and a side surface of the conductor 242e. Furthermore, the conductor 240a and the conductor 240b are provided so as not to be in contact with the insulator 212, the insulator 214, the insulator 282, or the insulator 215.

When the semiconductor device of one embodiment of the present invention has the above structure, the insulator 212, the insulator 282, and the insulator 215 do not need to be processed at the time of providing an opening that penetrates the memory layer 11_1 to the memory layer 11_n and reaches the conductor 209a after the memory layer 11_n illustrated in FIG. 8 is formed. Thus, the opening can be formed under one condition even when the insulator 212, the insulator 282, and the insulator 215 are formed using materials that are easily processed under different conditions from materials for the other insulators. This can widen the range of choices for materials that can be used for the insulators. Note that the conductor 240a and the conductor 240b can each be formed by embedding a conductive film in the opening.

FIG. 10B is a cross-sectional view illustrating a structure example of the transistor illustrated in FIG. 10A in the channel width direction, i.e., in the Y direction.

In the example illustrated in FIG. 10B, the insulator 212 is provided over the insulator 210, the insulator 214 is provided over the insulator 212, the insulator 216a is provided over the insulator 214, and the conductor 205a1 is provided in the opening provided in the insulator 216a. The insulator 222 is provided over the conductor 205a1 and the insulator 216a, the insulator 224 and the insulator 275 are provided over the insulator 222, and the metal oxide 230 is provided over the insulator 224. The side surface of the insulator 224 and the top surface and the side surface of the metal oxide 230 are covered with the insulator 253, the insulator 254, and the conductor 260. The insulator 253, the insulator 254, and the conductor 260 are provided in an opening 258 of the insulator 280 provided over the insulator 275. The insulator 282 is provided over the insulator 253, the insulator 254, the conductor 260, and the insulator 280, and the insulator 285 is provided over the insulator 282.

Here, the conductor 260 including the region functioning as the first gate electrode can be regarded as covering not only the top surface but also the side surface of the metal oxide 230.

In this specification and the like, a transistor structure in which a channel formation region is electrically surrounded by at least the electric field of a first gate electrode is referred to as a surrounded channel (S-channel) structure. The S-channel structure disclosed in this specification and the like has a structure that is different from a Fin-type structure and a planar structure. The S-channel structure disclosed in this specification and the like can be regarded as a kind of the Fin-type structure. Note that in this specification and the like, the Fin-type structure refers to a structure in which a gate electrode is placed to cover at least two or more surfaces (specifically, two surfaces, three surfaces, or four surfaces) of a channel. With the use of the Fin-type structure and the S-channel structure, a transistor with high resistance to a short-channel effect, i.e., a transistor in which a short-channel effect is unlikely to occur, can be obtained.

When the transistor included in the semiconductor device of this embodiment has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or an LGAA (Lateral Gate All Around) structure. In the transistor having the S-channel structure, the GAA structure, or the LGAA structure, the channel formation region that is formed at the interface between an oxide and a gate insulator or in the vicinity of the interface can be the entire bulk of the metal oxide. Accordingly, the density of current flowing in the transistor can be improved, and it can be expected to improve the on-state current of the transistor or increase the field-effect mobility of the transistor.

Although FIG. 10B illustrates a transistor with an S-channel structure as the transistor, the semiconductor device of one embodiment of the present invention is not limited thereto. For example, a transistor structure that can be used in one embodiment of the present invention may be one or more selected from a planar structure, a Fin-type structure, and a GAA structure.

Note that the cross-sectional shape of the metal oxide 230 is not limited to the structure illustrated in FIG. 10B. For example, the metal oxide 230 may have a curved surface between the side surface and the top surface. Thus, coverage with a film formed over the metal oxide 230 can be improved.

Next, the transistors included in the semiconductor device of this embodiment are described in detail.

The metal oxide 230 preferably includes the metal oxide 230a over the insulator 224 and the metal oxide 230b over the metal oxide 230a. Including the metal oxide 230a under the metal oxide 230b makes it possible to inhibit diffusion of impurities into the metal oxide 230b from components formed below the metal oxide 230a.

Although an example in which the metal oxide 230 has a two-layer structure of the metal oxide 230a and the metal oxide 230b is described in this embodiment, the present invention is not limited thereto. For example, the metal oxide 230 may have a single-layer structure of the metal oxide 230b or a stacked-layer structure of three or more layers.

The metal oxide 230b in the transistor includes a channel formation region and a source region and a drain region provided such that the channel formation region is interposed therebetween. At least part of the channel formation region overlaps with the conductor 260. The source region overlaps with one of a pair of conductors 242, and the drain region overlaps with the other of the pair of conductors 242.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (low-resistance region) having a higher carrier concentration than the channel formation region.

Note that the carrier concentration of the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1×10⁻⁹ cm⁻³.

In order to reduce the carrier concentration in the metal oxide 230b, the impurity concentration in the metal oxide 230b is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration may be referred to as a highly purified intrinsic or substantially highly purified intrinsic oxide semiconductor (or metal oxide).

In order to obtain stable electrical characteristics of the transistor, reducing the impurity concentration in the metal oxide 230b is effective. In order to reduce the impurity concentration in the metal oxide 230b, it is preferable that the impurity concentration in an adjacent film be also reduced. Examples of impurities include hydrogen, nitrogen, an alkali metal, an alkaline earth metal, iron, nickel, and silicon. Note that an impurity in the metal oxide 230b refers to, for example, an element other than the main components of the metal oxide 230b. For example, an element with a concentration lower than 0.1 atomic % can be regarded as an impurity.

Note that the channel formation region, the source region, and the drain region may each be formed not only in the metal oxide 230b but also in the metal oxide 230a.

In the metal oxide 230, the boundaries between the regions are difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

A metal oxide functioning as a semiconductor (hereinafter, also referred to as an oxide semiconductor) is preferably used as the metal oxide 230.

The metal oxide functioning as a semiconductor preferably has a band gap higher than or equal to 2 eV, further preferably higher than or equal to 2.5 eV. With use of a metal oxide having a wide bandgap, the off-state current of the transistor can be reduced.

As the metal oxide 230, a metal oxide such as indium oxide, gallium oxide, or zinc oxide is preferably used, for example. Alternatively, as the metal oxide 230, a metal oxide containing two or three selected from indium, an element M, and zinc is preferably used, for example. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin. Note that a metal oxide containing indium, the element M, and zinc is referred to as In-M-Zn oxide in some cases.

The metal oxide 230 preferably has a stacked-layer structure of a plurality of oxide layers with different chemical compositions. For example, the atomic ratio of the element M to a metal element that is a main component of the metal oxide used as the metal oxide 230a is preferably greater than the atomic ratio of the element M to a metal element that is a main component of the metal oxide used as the metal oxide 230b. Moreover, the atomic ratio of the element M to In in the metal oxide used as the metal oxide 230a is preferably greater than the atomic ratio of the element M to In in the metal oxide used as the metal oxide 230b. With this structure, impurities and oxygen can be inhibited from diffusing into the metal oxide 230b from the components formed below the metal oxide 230a.

Furthermore, the atomic ratio of In to the element M in the metal oxide used as the metal oxide 230b is preferably greater than the atomic ratio of In to the element M in the metal oxide used as the metal oxide 230a. With this structure, the transistor can have high on-state current and high frequency characteristics.

When the metal oxide 230a and the metal oxide 230b contain a common element as the main component besides oxygen, the density of defect states at an interface between the metal oxide 230a and the metal oxide 230b can be decreased. The density of defect states at the interface between the metal oxide 230a and the metal oxide 230b can be decreased. Thus, the influence of interface scattering on carrier conduction is small, and the transistor can have high on-state current and high frequency characteristics.

Specifically, as the metal oxide 230a, a metal oxide with a composition of In:M:Zn=1:3:4 [atomic ratio] or in the neighborhood thereof or a composition of In:M:Zn=1:1:0.5 [atomic ratio] or in the neighborhood thereof can be used. As the metal oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of InM:Zn=4:2:3 [atomic ratio] or in the neighborhood thereof can be used. Note that a composition in the neighborhood includes the range of ±30% of an intended atomic ratio. Gallium is preferably used as the element M. In the case where a single layer of the metal oxide 230b is provided as the metal oxide 230, a metal oxide that can be used as the metal oxide 230a may be used as the metal oxide 230b.

When the metal oxide is deposited by a sputtering method, the above atomic ratio is not limited to the atomic ratio of the deposited metal oxide and may be the atomic ratio of a sputtering target used for depositing the metal oxide.

The metal oxide 230b preferably has crystallinity. It is particularly preferable to use a CAAC-OS (c-axis aligned crystalline oxide semiconductor) as the metal oxide 230b.

The CAAC-OS is a metal oxide having a dense structure with high crystallinity and small amounts of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as CAAC-OS, is used as the metal oxide 230b, oxygen extraction from the metal oxide 230b by the source electrode or the drain electrode can be inhibited. This can reduce oxygen extraction from the metal oxide 230b even when heat treatment is performed; thus, the transistor is stable with respect to high temperatures in a manufacturing process (what is called thermal budget).

A transistor using an oxide semiconductor is likely to have its electrical characteristics changed by impurities and oxygen vacancies in a region where a channel is formed in the oxide semiconductor, which might affect the reliability. In some cases, a defect that is an oxygen vacancy into which hydrogen in the vicinity of the oxygen vacancy has entered (hereinafter sometimes referred to as V_{O}H) is formed, which generates an electron serving as a carrier. Therefore, when the region where a channel is formed in the oxide semiconductor includes oxygen vacancies, the transistor is likely to have normally-on characteristics (characteristics with which, even when no voltage is applied to the gate electrode, the channel exists and current flows through the transistor). Therefore, impurities, oxygen vacancies, and V_{O}H are preferably reduced as much as possible in the region where a channel is formed in the oxide semiconductor. In other words, it is preferable that the region of the oxide semiconductor where a channel is formed have a reduced carrier concentration and be of an i-type (intrinsic) or substantially i-type.

As a countermeasure against the above, an insulator containing oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into a conductor such as the gate electrode, the source electrode, or the drain electrode, the conductor might be oxidized and the conductivity might be impaired, for example, so that electrical characteristics and reliability of the transistor might be adversely affected.

Accordingly, in the oxide semiconductor, the channel formation region is preferably an i-type or substantially i-type region with a reduced carrier concentration, whereas the source region and the drain region are preferably n-type regions with high carrier concentrations. That is, the amounts of oxygen vacancies and V_{O}H in the channel formation region of the oxide semiconductor are preferably reduced. Supply of an excess amount of oxygen to the source region and the drain region and excessive reduction in the amount of V_{O}H in the source region and the drain region are preferably inhibited. Furthermore, a structure is preferable in which a reduction in the conductivity of the conductor 260, the conductor 242, and the like is inhibited. For example, a structure is preferable in which oxidation of the conductor 260, the conductor 242, and the like is inhibited. Note that hydrogen in the oxide semiconductor can form V_{O}H; thus, the hydrogen concentration needs to be reduced in order to reduce the amount of V_{O}H.

The semiconductor device of this embodiment thus has a structure in which the hydrogen concentration in the channel formation region is reduced, oxidation of the conductor 242 and the conductor 260 is inhibited, and a reduction in the hydrogen concentration in the source region and the drain region is inhibited.

The insulator 253 in contact with the channel formation region of the metal oxide 230b preferably has a function of capturing and fixing hydrogen. Thus, the hydrogen concentration in the channel formation region of the metal oxide 230b can be reduced. Accordingly, V_{O}H in the channel formation region can be reduced, so that the channel formation region can be an i-type or substantially i-type region.

Examples of insulators having a function of capturing and fixing hydrogen include a metal oxide having an amorphous structure. As the insulator 253, for example, a metal oxide, such as magnesium oxide or an oxide containing one or both of aluminum and hafnium, is preferably used. In such a metal oxide having an amorphous structure, an oxygen atom has a dangling bond and sometimes has a property of capturing or fixing hydrogen with the dangling bond. That is, the metal oxide having an amorphous structure has high capability of capturing or fixing hydrogen.

A high dielectric constant (high-k) material is preferably used for the insulator 253. An example of the high-k material is an oxide containing one or both of aluminum and hafnium. With the use of the high-k material for the insulator 253, a gate potential applied during the operation of the transistor can be reduced while the physical thickness of the gate insulator is maintained. In addition, the equivalent oxide thickness (EOT) of the insulator functioning as the gate insulator can be reduced.

As described above, for the insulator 253, an oxide containing one or both of aluminum and hafnium is preferably used, an oxide containing one or both of aluminum and hafnium and having an amorphous structure is further preferably used, and hafnium oxide having an amorphous structure is still further preferably used. In this embodiment, hafnium oxide is used for the insulator 253. In this case, the insulator 253 is an insulator that contains at least oxygen and hafnium. The hafnium oxide has an amorphous structure. In this case, the insulator 253 has an amorphous structure.

Alternatively, as the insulator 253, an insulator having a thermally stable structure, such as silicon oxide or silicon oxynitride, may be used. For example, the insulator 253 may have a stacked-layer structure including aluminum oxide and silicon oxide or silicon oxynitride over the aluminum oxide. For another example, the insulator 253 may have a stacked-layer structure including aluminum oxide, silicon oxide or silicon oxynitride over the aluminum oxide, and hafnium oxide over the silicon oxide or silicon oxynitride.

In order to inhibit oxidation of the conductor 242 and the conductor 260, a barrier insulator against oxygen is preferably provided in the vicinity of each of the conductor 242 and the conductor 260. In the semiconductor device described in this embodiment, the insulator corresponds to the insulator 253, the insulator 254, and the insulator 275, for example.

Note that in this specification and the like, a barrier insulator refers to an insulator having a barrier property. A barrier property in this specification and the like means a function of inhibiting diffusion of a targeted substance (also referred to as having low permeability). In addition, a barrier property in this specification means a function of capturing and fixing (also referred to as gettering) a targeted substance.

Examples of the barrier insulator against oxygen include an oxide containing one or both of aluminum and hafnium, magnesium oxide, gallium oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate). For example, each of the insulator 253, the insulator 254, and the insulator 275 preferably has a single-layer structure or a stacked-layer structure of the barrier insulator against oxygen.

The insulator 253 preferably has a barrier property against oxygen. The insulator 253 is preferably less permeable to oxygen than at least the insulator 280 is. The insulator 253 includes a region in contact with the side surface of the conductor 242. When the insulator 253 has a barrier property against oxygen, oxidation of the side surface of the conductor 242 and formation of an oxide film on the side surface can be inhibited. Accordingly, a decrease in the on-state current or field-effect mobility of the transistor can be inhibited.

The insulator 253 is provided in contact with the top surface and the side surface of the metal oxide 230b, the side surface of the metal oxide 230a, the side surface of the insulator 224, and the top surface of the insulator 222. When the insulator 253 has a barrier property against oxygen, release of oxygen from the channel formation region of the metal oxide 230b caused by heat treatment can be inhibited, for example. This can reduce formation of oxygen vacancies in the metal oxide 230a and the metal oxide 230b.

Even when an excess amount of oxygen is contained in the insulator 280, in contrast, oxygen can be inhibited from being excessively supplied to the metal oxide 230a and the metal oxide 230b. Thus, it is possible to inhibit excessive oxidation of the source region and the drain region and a decrease in the on-state current or field-effect mobility of the transistor.

The oxide containing one or both of aluminum and hafnium has a barrier property against oxygen and thus can be suitably used for the insulator 253.

The insulator 254 preferably has a barrier property against oxygen. The insulator 254 is provided between the conductor 260 and the channel formation region of the metal oxide 230 and between the insulator 280 and the conductor 260. Such a structure can inhibit diffusion of oxygen contained in the channel formation region of the metal oxide 230 into the conductor 260 and formation of oxygen vacancies in the channel formation region of the metal oxide 230. Oxygen contained in the metal oxide 230 and oxygen contained in the insulator 280 can be inhibited from diffusing into the conductor 260 and oxidizing the conductor 260. The insulator 254 is preferably less permeable to oxygen than at least the insulator 280 is. For example, silicon nitride is preferably used for the insulator 254. In this case, the insulator 254 is an insulator that contains at least nitrogen and silicon.

The insulator 254 preferably has a barrier property against hydrogen. Accordingly, diffusion of impurities contained in the conductor 260, such as hydrogen, into the metal oxide 230b can be prevented.

The insulator 275 preferably has a barrier property against oxygen. The insulator 275 is provided between the insulator 280 and the conductor 242. With this structure, oxygen contained in the insulator 280 can be inhibited from diffusing into the conductor 242. Thus, the conductor 242 can be inhibited from being oxidized by oxygen contained in the insulator 280, so that an increase in resistivity and a reduction in on-state current can be inhibited. The insulator 275 is preferably less permeable to oxygen than at least the insulator 280 is. For example, silicon nitride is preferably used for the insulator 275. In this case, the insulator 275 is an insulator that contains at least nitrogen and silicon.

In order to inhibit a reduction in hydrogen concentration in the source region and the drain region in the metal oxide 230, a barrier insulator against hydrogen is preferably provided in the vicinity of each of the source region and the drain region. In the semiconductor device described in this embodiment, the barrier insulator against hydrogen is, for example, the insulator 275. When the insulator 275 has a barrier property against hydrogen, capturing and fixing of hydrogen in the source region and the drain region by the insulator 253 can be inhibited. Thus, the source region and the drain region can be n-type regions.

With the above structure, the channel formation region can be an i-type or substantially i-type region, and the source region and the drain region can be n-type regions; thus, a semiconductor device with excellent electrical characteristics can be provided. The semiconductor device with the above structure can have favorable electrical characteristics even when being miniaturized or highly integrated. Furthermore, miniaturization of the transistor can improve high-frequency characteristics. Specifically, the cutoff frequency can be improved.

Examples of the barrier insulator against hydrogen include oxides such as aluminum oxide, hafnium oxide, and tantalum oxide and nitrides such as silicon nitride. For example, the insulator 275 preferably has a single-layer structure or a stacked-layer structure of the above barrier insulator against hydrogen.

The insulator 253 and the insulator 254 each function as part of the gate insulator. The insulator 253 and the insulator 254 are provided together with the conductor 260 in an opening formed in the insulator 280 and the like. The thickness of the insulator 253 and the thickness of the insulator 254 are preferably small for scaling down of the transistor. The thickness of the insulator 253 is preferably larger than or equal to 0.1 nm and smaller than or equal to 5.0 nm, further preferably larger than or equal to 0.5 nm and smaller than or equal to 5.0 nm, still further preferably larger than or equal to 1.0 nm and smaller than 5.0 nm, yet further preferably larger than or equal to 1.0 nm and smaller than or equal to 3.0 nm. The thickness of the insulator 254 is preferably larger than or equal to 0.1 nm and smaller than or equal to 5.0 nm, further preferably larger than or equal to 0.5 nm and smaller than or equal to 3.0 nm, still further preferably larger than or equal to 1.0 nm and smaller than or equal to 3.0 nm. Note that at least part of each of the insulator 253 and the insulator 254 includes a region having a thickness like the above-described thickness.

To form the insulator 253 having a small thickness as described above, an atomic layer deposition (ALD) method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because deposition at a lower temperature is possible.

An ALD method, which enables an atomic layer to be deposited one by one has advantages such as deposition of an extremely thin film, deposition on a component with a high aspect ratio, deposition of a film with a small number of defects such as pinholes, deposition with excellent coverage, and low-temperature deposition. Therefore, the insulator 253 can be deposited on the side surface of the opening portion formed in the insulator 280 and the like, the side end portion of the conductor 242, and the like, with a small thickness like the above-described thickness and good coverage.

Note that some of precursors usable in an ALD method contain carbon, for example. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

For example, silicon nitride deposited by a PEALD method can be used for the insulator 254.

Note that when an insulator having a function of inhibiting passage of oxygen and impurities such as hydrogen, e.g., hafnium oxide, is used as the insulator 253, the insulator 253 can also have the function of the insulator 254. In such a case, the structure without the insulator 254 enables simplification of the manufacturing process and the improvement in productivity of the semiconductor device.

In addition to the above structure, the semiconductor device of this embodiment preferably has a structure in which hydrogen is inhibited from entering the transistor. For example, an insulator having a function of inhibiting diffusion of hydrogen is preferably provided to cover one or both of the upper portion and the lower portion of the transistor. In the semiconductor device described in this embodiment, the insulator corresponds to the insulator 212, for example.

As the insulator 212, an insulator having a function of inhibiting diffusion of hydrogen is preferably used. This can inhibit diffusion of hydrogen into the transistor from below the insulator 212. As the insulator 212, the above-described insulator that can be used for the insulator 275 can be used.

One or more of the insulator 212, the insulator 214, and the insulator 282 preferably function as a barrier insulating film, which inhibits diffusion of impurities such as water and hydrogen into the transistor from the substrate side or from above the transistor. Thus, one or more of the insulator 212, the insulator 214, and the insulator 282 preferably contain an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), or a copper atom (an insulating material through which the impurities are less likely to pass). Alternatively, it is preferable to contain an insulating material having a function of inhibiting diffusion of oxygen (e.g., at least one of an oxygen atom, an oxygen molecule, and the like) (an insulating material through which the oxygen is less likely to pass).

The insulator 212, the insulator 214, and the insulator 282 each preferably include an insulator having a function of inhibiting diffusion of oxygen and impurities such as water and hydrogen; for example, aluminum oxide, magnesium oxide, hafnium oxide, gallium oxide, indium gallium zinc oxide, silicon nitride, silicon nitride oxide, or the like can be used. For example, silicon nitride, which has a higher hydrogen barrier property, is preferably used for the insulator 212. For example, the insulator 212, the insulator 214, and the insulator 282 each preferably contain aluminum oxide, magnesium oxide, or the like, which has an excellent function of capturing and fixing hydrogen. Accordingly, impurities such as water and hydrogen can be inhibited from diffusing from the substrate side to the transistor side through the insulator 212 and the insulator 214. Furthermore, impurities such as water and hydrogen can be inhibited from diffusing to the transistor side from an interlayer insulating film and the like placed outside the insulator 282. Moreover, oxygen contained in the insulator 224 and the like can be inhibited from diffusing to the substrate side. In addition, oxygen contained in the insulator 280 and the like can be inhibited from diffusing to the components over the transistor through the insulator 282 and the like. In this manner, it is preferable that the transistor be surrounded by the insulators having a function of inhibiting diffusion of oxygen and impurities such as water and hydrogen.

The conductor 205a is placed to overlap with the metal oxide 230 and the conductor 260. Here, the conductor 205a is preferably provided to fill an opening portion formed in the insulator 216a. Part of the conductor 205a is embedded in the insulator 214 in some cases.

The conductor 205a may have a single-layer structure or a stacked-layer structure. For example, FIG. 10A illustrates an example in which the conductor 205a has a two-layer stacked structure of a first conductor and a second conductor. The first conductor of the conductor 205a is provided in contact with the bottom surface and sidewall of the opening portion provided in the insulator 216a. The second conductor of the conductor 205a is provided to be embedded in a depressed portion formed in the first conductor of the conductor 205a. Here, the top surface of the second conductor of the conductor 205a is substantially level with the top surface of the first conductor of the conductor 205a and the top surface of the insulator 216a.

Here, the first conductor of the conductor 205a preferably contains a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to contain a conductive material having a function of inhibiting diffusion of oxygen (e.g., at least one of an oxygen atom, an oxygen molecule, and the like).

When a conductive material having a function of inhibiting diffusion of hydrogen is used for the first conductor of the conductor 205a, impurities such as hydrogen contained in the second conductor of the conductor 205a can be prevented from diffusing into the metal oxide 230 through the insulator 216a, the insulator 224, and the like. When a conductive material having a function of inhibiting diffusion of oxygen is used for the first conductor of the conductor 205a, the conductivity of the second conductor of the conductor 205a can be inhibited from being lowered because of oxidation. Examples of the conductive material having a function of inhibiting diffusion of oxygen include titanium, titanium nitride, tantalum, tantalum nitride, ruthenium, and ruthenium oxide. The first conductor of the conductor 205a can have a single-layer structure or a stacked-layer structure of the above conductive material. For example, the first conductor of the conductor 205a preferably contains titanium nitride.

A conductive material containing tungsten, copper, or aluminum as its main component is preferably used for the second conductor of the conductor 205a. For example, the second conductor of the conductor 205a preferably contains tungsten.

The conductor 205a can function as the second gate electrode. In that case, by changing a potential applied to the conductor 205a not in conjunction with but independently of a potential applied to the conductor 260, the threshold voltage (Vth) of the transistor can be controlled. In particular, by applying a negative potential to the conductor 205a, Vth of the transistor can be higher, and its off-state current can be reduced. Thus, drain current at the time when a potential applied to the conductor 260 is 0 V can be lower in the case where a negative potential is applied to the conductor 205a than in the case where the negative potential is not applied to the conductor 205a.

The electrical resistivity of the conductor 205a is designed in consideration of the potential applied to the conductor 205a, and the thickness of the conductor 205a is set in accordance with the electrical resistivity. The thickness of the insulator 216a is substantially equal to the thickness of the conductor 205a. Here, the conductor 205a and the insulator 216a are preferably as thin as possible in the allowable range of the design of the conductor 205a. When the thickness of the insulator 216a is reduced, the absolute amount of impurities such as hydrogen contained in the insulator 216a can be reduced, so that diffusion of the impurities into the metal oxide 230 can be inhibited.

The insulator 222 and the insulator 224 function as a gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

The insulator 222 preferably includes an insulator containing an oxide of one or both of aluminum and hafnium, which is an insulating material. For the insulator, aluminum oxide, hafnium oxide, an oxide containing aluminum and hafnium (hafnium aluminate), or the like is preferably used. Alternatively, an oxide containing hafnium and zirconium, e.g., a hafnium zirconium oxide, is preferably used. In the case where the insulator 222 is formed using such a material, the insulator 222 functions as a layer that inhibits release of oxygen from the metal oxide 230 to the substrate side and diffusion of impurities such as hydrogen from the periphery of the transistor into the metal oxide 230. Thus, providing the insulator 222 can inhibit diffusion of impurities such as hydrogen to the inside of the transistor and inhibit generation of oxygen vacancies in the metal oxide 230. Moreover, the first conductor of the conductor 205a can be inhibited from reacting with oxygen contained in the insulator 224 and the metal oxide 230.

Alternatively, aluminum oxide, bismuth oxide, germanium oxide, niobium oxide, silicon oxide, titanium oxide, tungsten oxide, yttrium oxide, or zirconium oxide may be added to the above insulators, for example. Alternatively, the insulator may be subjected to nitriding treatment. A stack of silicon oxide, silicon oxynitride, or silicon nitride over the above insulators may be used for the insulator 222.

For example, the insulator 222 may have a single-layer structure or a stacked-layer structure of an insulator(s) containing what is called a high-k material such as aluminum oxide, hafnium oxide, tantalum oxide, zirconium oxide, or hafnium zirconium oxide. As miniaturization and high integration of transistors progress, a problem such as leakage current may arise because of a thinner gate insulator. When a high-k material is used for the insulator functioning as a gate insulator, a gate potential at the time of the operation of the transistor can be reduced while the physical thickness is maintained. Furthermore, a substance with a high dielectric constant such as lead zirconate titanate (PZT), strontium titanate (SrTiO₃), or (Ba,Sr)TiO₃ (BST) can be used for the insulator 222 in some cases.

The insulator 224 that is in contact with the metal oxide 230 preferably contains silicon oxide or silicon oxynitride, for example.

Note that the insulator 222 and the insulator 224 may each have a stacked-layer structure of two or more layers. In that case, without limitation to a stacked-layer structure formed of the same material, a stacked-layer structure formed of different materials may be employed.

A conductive material that is not easily oxidized or a conductive material having a function of inhibiting oxygen diffusion is preferably used for each of the conductor 242 and the conductor 260. Examples of the conductive material include a conductive material containing nitrogen and a conductive material containing oxygen. This can inhibit a reduction in the conductivity of the conductor 242 and the conductor 260. In the case where a conductive material containing metal and nitrogen is used for the conductor 242 and the conductor 260, the conductor 242 and the conductor 260 are conductors that contain at least metal and nitrogen.

The conductor 242 may have a single-layer structure or a stacked-layer structure. The conductor 260 may have a single-layer structure or a stacked-layer structure.

For example, in FIG. 10A, the conductor 242 has a two-layer structure of a first conductor and a second conductor over the first conductor. In that case, for the first conductor of the conductor 242 in contact with the metal oxide 230b, it is preferable to use a conductive material that is not easily oxidized or a conductive material having a function of inhibiting oxygen diffusion. Thus, the conductivity of the conductor 242 can be inhibited from being reduced. For the first conductor of the conductor 242, a material that is likely to absorb (extract) hydrogen is preferably used, in which case the hydrogen concentration in the metal oxide 230 can be reduced.

The second conductor of the conductor 242 preferably has higher conductivity than the first conductor of the conductor 242. For example, the thickness of the second conductor of the conductor 242 is preferably larger than the thickness of the first conductor of the conductor 242.

For example, tantalum nitride or titanium nitride can be used for the first conductor of the conductor 242, and tungsten can be used for the second conductor of the conductor 242.

To inhibit a reduction in the conductivity of the conductor 242, an oxide having crystallinity, such as a CAAC-OS, is preferably used as the metal oxide 230b. Specifically, a metal oxide containing indium, zinc, and one or more selected from gallium, aluminum, and tin is preferably used. When a CAAC-OS is used, oxygen extraction from the metal oxide 230b by the conductor 242 can be inhibited. Furthermore, it is possible to inhibit a reduction in the conductivity of the conductor 242.

As the conductor 242, for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

Note that, for example, hydrogen contained in the metal oxide 230b diffuses into the conductor 242 in some cases. In particular, when a nitride containing tantalum is used for the conductor 242, for example, hydrogen contained in the metal oxide 230b is likely to diffuse into the conductor 242, and the diffused hydrogen is bonded to nitrogen contained in the conductor 242 in some cases. That is, hydrogen contained in the metal oxide 230b or the like is sometimes absorbed by the conductor 242, for example.

The top surface of the conductor 260 is placed to be substantially level with the uppermost portion of the insulator 254, the uppermost portion of the insulator 253, and the top surface of the insulator 280.

The conductor 260 functions as the first gate electrode of the transistor. The conductor 260 preferably includes a first conductor and a second conductor over the first conductor. For example, the first conductor of the conductor 260 is preferably placed to cover the bottom surface and a side surface of the second conductor of the conductor 260.

For example, the conductor 260 illustrated in FIG. 10A has a two-layer structure. In that case, for the first conductor of the conductor 260, it is preferable to use a conductive material that is not easily oxidized or a conductive material having a function of inhibiting oxygen diffusion.

For the first conductor of the conductor 260, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

In addition, when the first conductor of the conductor 260 has a function of inhibiting oxygen diffusion, for example, the conductivity of the second conductor of the conductor 260 can be inhibited from being lowered because of oxidation due to oxygen contained in the insulator 280. As the conductive material having a function of inhibiting diffusion of oxygen, for example, titanium, titanium nitride, tantalum, tantalum nitride, ruthenium, or ruthenium oxide is preferably used.

As the conductor 260, a conductor having high conductivity is preferably used. For example, a conductive material containing tungsten, copper, or aluminum as its main component can be used for the second conductor of the conductor 260. The second conductor of the conductor 260 may have a stacked-layer structure; for example, a stacked-layer structure of the conductive material and titanium or titanium nitride may be employed.

In the transistor, the conductor 260 is formed in a self-aligned manner to fill the opening formed in the insulator 280, for example. The formation of the conductor 260 in this manner allows the conductor 260 to be placed properly in a region between the pair of conductors 242 without alignment.

The top surfaces of the insulator 216a, the insulator 280, the insulator 285, the insulator 287, the insulator 216b, the insulator 181, and the insulator 185 may be planarized.

The concentration of impurities such as water and hydrogen in the insulator 280 is preferably reduced. For example, the insulator 280 preferably contains an oxide containing silicon, such as silicon oxide or silicon oxynitride.

Note that the sidewall of the insulator 280 in the opening portion in the insulator 280 may be substantially perpendicular to the top surface of the insulator 222 or may have a tapered shape. The tapered sidewall can improve the coverage with the insulator 253 provided in the opening portion of the insulator 280, for example; as a result, the number of defects such as voids can be reduced.

Note that in this specification and the like, a tapered shape refers to a shape such that at least part of the side surface of a component is inclined with respect to the substrate surface or a formation surface. For example, the tapered shape preferably includes a region where the angle formed between the inclined side surface and the substrate surface or the formation surface (the angle is hereinafter referred to as a taper angle in some cases) is less than 90°. Note that the side surface of the component and the substrate surface are not necessarily completely flat and may be substantially flat with a slight curvature or substantially flat with slight unevenness.

For the conductor 161 and the conductor 162 included in the capacitor 101, any of the materials that can be used for the conductor 205a, the conductor 242, and the conductor 260 can be used.

The conductor 161 and the conductor 162 are preferably deposited by a deposition method that offers excellent coverage, such as an ALD method or a CVD method.

For the conductor 161 and the conductor 162, metals such as aluminum, titanium, chromium, nickel, copper, yttrium, zirconium, molybdenum, silver, tantalum, and tungsten, and an alloy containing any of these metals as its main component can be used. Alternatively, a metal nitride film containing any of the above elements as a component (a titanium nitride film, a molybdenum nitride film, or a tungsten nitride film) or the like can be used. Alternatively, a single layer or a stacked-layer structure including a film containing these materials can be used.

The conductor is preferably in contact with the ferroelectric material, in which case polarization is likely to occur in the ferroelectric material. For the conductor 161 and the conductor 162, a material that easily causes polarization in the ferroelectric material is preferably used.

Heat treatment is preferably performed after the conductor 161, the insulator 163, and the conductor 162 are stacked sequentially, in which case the ferroelectricity of the insulator 163 can sometimes be improved. The heat treatment can be performed by using an RTA apparatus, a resistance heating furnace, or a microwave heating apparatus. It is particularly preferable to use an RTA apparatus because a film with particularly excellent ferroelectricity can be obtained in some cases. As the RTA apparatus, a GRTA (Gas Rapid Thermal Anneal) apparatus or an LRTA (Lamp Rapid Thermal Anneal) apparatus can be used.

Titanium nitride is preferably used for each of the conductor 161 and the conductor 162.

Titanium nitride is preferably used for a surface of the conductor 161 that is in contact with the insulator 163 (e.g., the top surface in the structure of FIG. 10). That is, in the case where the conductor 161 has a stacked-layer structure, the uppermost layer is preferably a titanium nitride layer.

Titanium nitride is preferably used for a surface of the conductor 162 that is in contact with the insulator 163 (e.g., the bottom surface in the structure of FIG. 10). That is, in the case where the conductor 162 has a stacked-layer structure, the lowermost layer is preferably a titanium nitride layer.

The insulator 163 included in the capacitor 101 is preferably formed using a material that can have ferroelectricity. As the material that can have ferroelectricity, the materials described in the above embodiment can be used.

Here, the thickness of the ferroelectric layer is preferably smaller than or equal to 200 nm, further preferably smaller than or equal to 150 nm.

In the case where a layer containing hafnium, zirconium, and oxygen is used as the ferroelectric layer, the thickness of the ferroelectric layer can be, for example, smaller than or equal to 100 nm, preferably smaller than or equal to 50 nm, further preferably smaller than or equal to 20 nm, still further preferably smaller than or equal to 15 nm, for example, larger than or equal to 2 nm and smaller than or equal to 15 nm, or larger than or equal to 8 nm and smaller than or equal to 12 nm.

The insulator 163 is preferably deposited by a deposition method that offers excellent coverage, such as an ALD method or a CVD method, and is particularly preferably formed by a thermal ALD method.

The conductor 240 preferably has a stacked-layer structure of a first conductor and a second conductor. For example, as illustrated in FIG. 10A, a structure can be employed in which the first conductor of the conductor 240 is provided in contact with the inner wall of the opening portion and the second conductor is provided on the inner side. The first conductor of the conductor 240 includes regions in contact with at least parts of the top surface of the conductor 209, the side surface of the insulator 212, the side surface of the insulator 216a, the top surface and the side surface of the conductor 242, the side surface of the insulator 280, the side surface of the insulator 285, the side surface of the insulator 287, and the side surface of the insulator 216b.

A conductive material having a function of inhibiting passage of impurities such as water and hydrogen is preferably used for the first conductor of the conductor 240. The first conductor of the conductor 240 can have a single-layer structure or a stacked-layer structure including one or more of tantalum, tantalum nitride, titanium, titanium nitride, ruthenium, and ruthenium oxide, for example. Thus, impurities such as water and hydrogen can be inhibited from entering the metal oxide 230 through the conductor 240.

The conductor 240 also functions as a wiring and thus is preferably formed using a conductor having high conductivity. For example, a conductive material containing tungsten, copper, or aluminum as its main component can be used for the second conductor of the conductor 240.

For example, it is preferable to use titanium nitride for the first conductor of the conductor 240 and tungsten for the second conductor of the conductor 240. In that case, the first conductor of the conductor 240 is a conductor that contains titanium and nitrogen, and the second conductor of the conductor 240 is a conductor that contains tungsten.

Note that the conductor 240 may have a single-layer structure or a stacked-layer structure of three or more layers. Although FIG. 8 illustrates an example in which the top surface of the conductor 240 is level with the top surface of the insulator 181, the top surface of the conductor 240 may be higher than the top surface of the insulator 181, for example.

The dielectric constant of each of the insulator 216a, the insulator 280, the insulator 285, the insulator 287, the insulator 216b, the insulator 181, and the insulator 185 is preferably lower than that of the insulator 163. The dielectric constant of the insulator 222 is preferably higher than that of each of the insulator 216a, the insulator 280, the insulator 285, the insulator 287, the insulator 216b, the insulator 181, and the insulator 185, for example. When an interlayer film of a material with a low dielectric constant is used as the insulator 216a, the insulator 280, the insulator 285, the insulator 287, the insulator 216b, the insulator 181, and the insulator 185, the parasitic capacitance generated between wirings can be reduced.

The dielectric constant of the insulator using the material that can have ferroelectricity is preferably higher than that of the insulator 222. For example, the dielectric constant of the insulator 163 is preferably higher than that of the insulator 222.

For example, the insulator 216a, the insulator 280, the insulator 285, the insulator 287, the insulator 216b, the insulator 181, and the insulator 185 each preferably contain one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride, which are thermally stable, are preferable. In particular, materials such as silicon oxide, silicon oxynitride, and porous silicon oxide are preferably used, in which case a region containing oxygen released by heating can be easily formed.

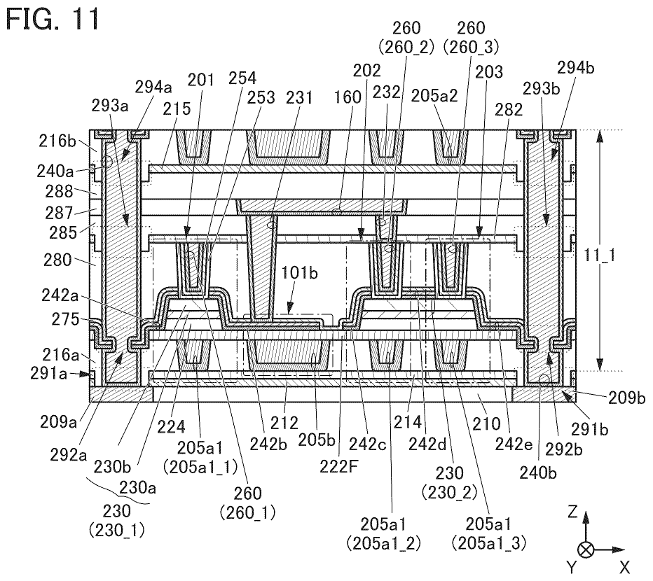

The memory layer 11 illustrated in FIG. 11 includes a capacitor 101b, the transistor 201, the transistor 202, and the transistor 203. FIG. 11 is different from FIG. 10 in that the memory layer 11 includes a conductor 205b and a conductor 160 and includes an insulator 222F instead of the insulator 222, and the like.

The capacitor 101b can correspond to the capacitor C1 described in the above embodiment. As in FIG. 10, the transistor 201, the transistor 202, and the transistor 203 can correspond respectively to the transistor M1, the transistor M2, and the transistor M3 included in the memory cell 10 described in the above embodiment and the conductor 240a and the conductor 240b can correspond to the wiring WBL and the wiring RBL, respectively.

In FIG. 11, the conductor 205b is embedded in an opening portion of the insulator 216a. The conductor 205b includes a region overlapping with the conductor 242b with the insulator 222F therebetween. The insulator 222F includes a region interposed between the conductor 205b and the conductor 242b. In the structure illustrated in FIG. 11, the conductor 205b preferably includes a region in contact with the bottom surface of the insulator 222F.

The conductor 205b includes a region functioning as the one electrode (also referred to as a lower electrode) of the capacitor 101b. The insulator 222F includes a region functioning as the dielectric of the capacitor 101. The conductor 242b includes a region functioning as the other electrode (also referred to as an upper electrode) of the capacitor 101b.

A material that can have ferroelectricity is preferably used for the insulator 222F. For the insulator 222F, the above description of the insulator 163 can be referred to.

The insulator 287 is provided over the insulator 285. An opening is provided in the insulator 287, and the conductor 160 is embedded in the opening. An insulator 288 is provided over the conductor 160 and the insulator 287. The insulator 215 is provided over the insulator 288. The insulator 216b provided with openings is provided over the insulator 215, and the conductor 205a2 and the conductor 205b are embedded in the openings. The conductor 160 can include a region in contact with a side surface of the insulator 288. The conductor 205a2 and the conductor 205b can include a region in contact with the side surface of the insulator 216b.

The dielectric constant of the insulator 288 is preferably lower than that of the insulator 163. Moreover, for example, the insulator 214 preferably has a higher dielectric constant than the insulator 288. When an interlayer film of a material with a low dielectric constant is used as the insulator 288, the parasitic capacitance generated between wirings can be reduced and the influence on the operation performance of the memory cell 10 can be inhibited. For the insulator 288, the description of the insulator 216a, the insulator 280, the insulator 285, the insulator 287, the insulator 216b, the insulator 181, and the insulator 185 can be referred to, for example.

Hereinafter, in the case where matters common to the conductor 205a1 and the conductor 205a2 are described, the term “conductor 205a” is used in some cases. In addition, in the case where matters common to the conductor 205a and the conductor 205b are described, the term “conductor 205” is used in some cases.

The conductor 242b and the conductor 160 are electrically connected to each other through the conductor 231. The conductor 260 included in the transistor 202 and the conductor 160 are electrically connected to each other through the conductor 232. In this manner, the conductor 242b including the region functioning as the other of the source electrode and the drain electrode of the transistor 201 is electrically connected to the conductor 260 including the region functioning as the gate electrode of the transistor 202 through the conductor 231, the conductor 160, and the conductor 232.

The conductor 160 includes a first conductor and a second conductor over the first conductor. For example, titanium nitride deposited by an ALD method can be used for the first conductor of the conductor 160, and tungsten deposited by a CVD method can be used for the second conductor of the conductor 160. Note that in the case where the adhesion of tungsten to the insulator 285 is sufficiently high, a single-layer structure of tungsten deposited by a CVD method may be used for the conductor 160.

Note that one of the insulator 288 and the insulator 215 is not necessarily provided in some cases.

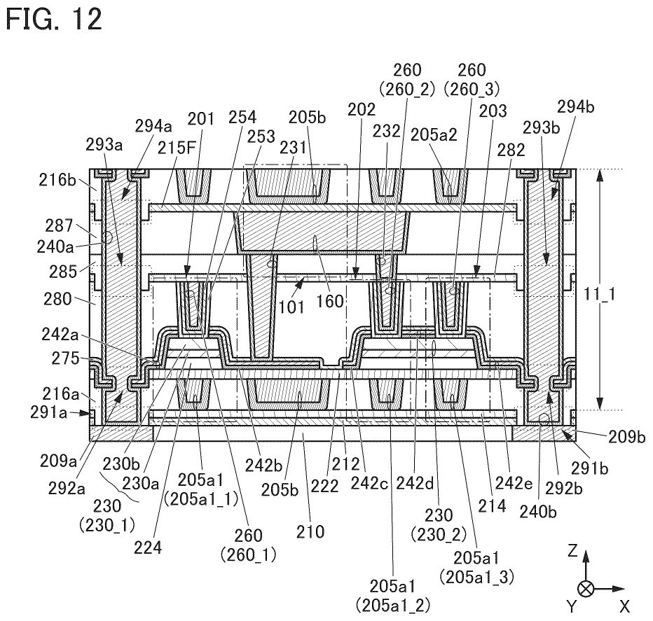

The memory layer 11 illustrated in FIG. 12 is different from that in FIG. 11 in including an insulator 215F instead of the insulator 215, including the insulator 222 instead of the insulator 222F, not including the insulator 288, and the like.

A material that can have ferroelectricity is preferably used for the insulator 215F. For the insulator 215F, the above description of the insulator 163 can be referred to.

Note that in FIG. 12, for example, the thickness of the insulator 222 is preferably larger than or equal to the thickness of the insulator 215F in some cases. Note that the insulator 222F may be used instead of the insulator 222 in some cases.

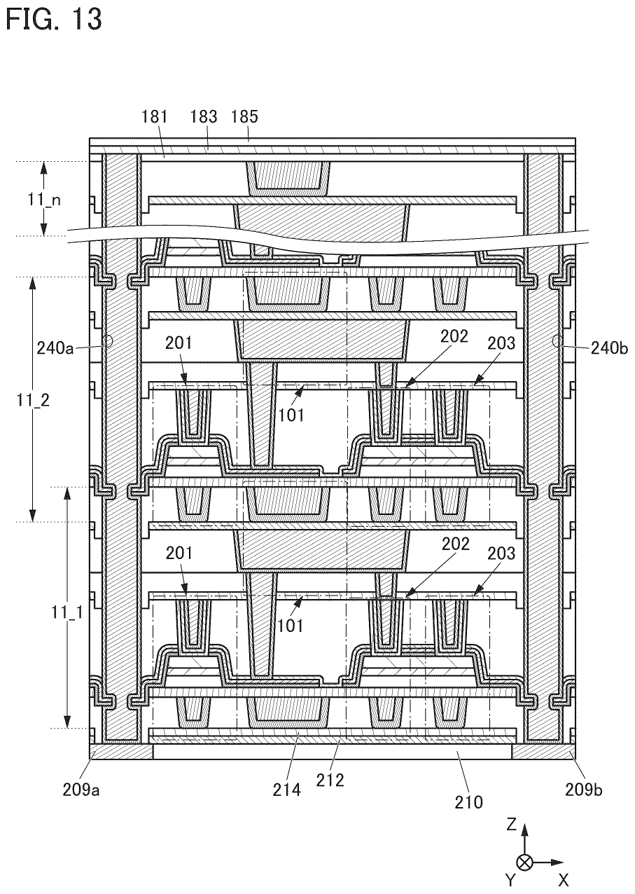

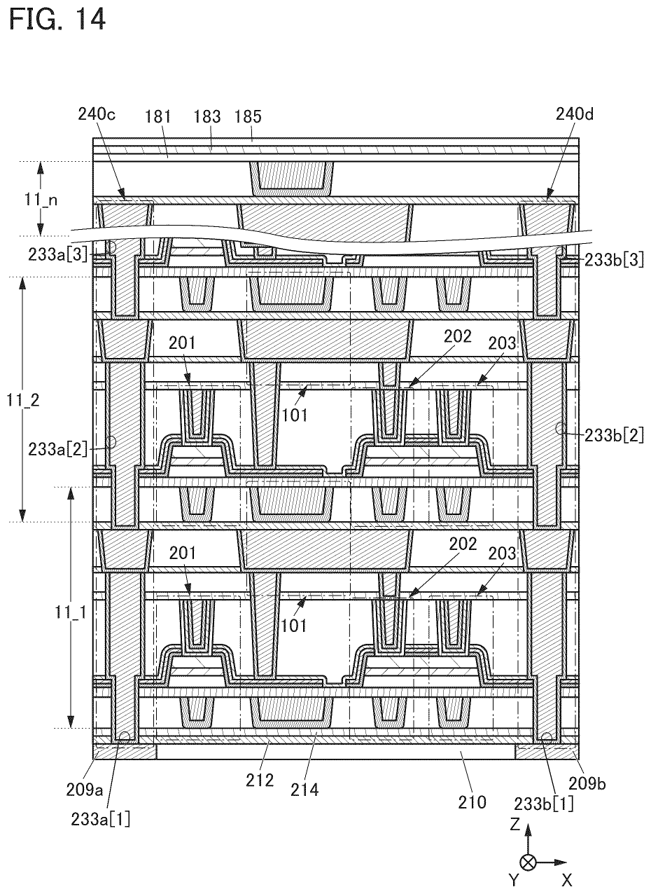

FIG. 13 and FIG. 14 each illustrate an example of a structure in which n stages of memory layers 11 illustrated in FIG. 12 are stacked. FIG. 13 illustrates a structure in which the conductor 240a and the conductor 240b illustrated in FIG. 8 are employed. FIG. 14 illustrates a structure in which the connection electrode 240c and the connection electrode 240d illustrated in FIG. 9 are employed.

In addition to the capacitor 101, the conductor 205b, the conductor 242b, and the insulator 222 interposed between the conductor 205b and the conductor 242b sometimes form a second capacitor in the memory layer 11 illustrated in FIG. 12 and FIG. 13. The conductor 205b and the conductor 242b can each function as an electrode of the second capacitor, and the insulator 222 can function as a dielectric. In the memory layer 11, the composite capacitance of the capacitor 101 and the second capacitor is sometimes formed. In the memory layer 11, the upper electrode of the capacitor 101 can be regarded as being shared by the lower electrode of the second capacitor included in another memory layer 11 which is one layer above.

For example, in the case where the composite capacitance of the capacitor 101 and the second capacitor is formed, memory layers vertically adjacent to each other among the stacked memory layers 11 do not share the wiring RBL[i,s] illustrated in FIG. 2, so that the influence of the second capacitor can be reduced in some cases.

Specifically, for example, it is possible that two wirings RBL[i,s] (e.g., a wiring RBL[i,s,A] and a wiring RBL[i,s,B]) are provided, the wiring RBL[i,s,A] is connected to the memory layer 11 which is an odd-numbered layer, and the wiring RBL[i,s,B] is connected to the memory layer 11 which is an even-numbered layer among the stacked memory layers 11. Alternatively, it is possible that the wiring RBL[i,s,B] is connected to the memory layer 11 which is the odd-numbered layer, and the wiring RBL[i,s,A] is connected to the memory layer 11 which is the even-numbered layer.

For example, the memory cell 10[i,j] included in a memory layer 11_h is electrically connected to the wiring WBL[i,s] and the wiring RBL[i,s,A]. The memory cell 10[i,j+1] included in the memory layer 11_h is electrically connected to the wiring WBL[i,s+1] and the wiring RBL[i,s,A]. The memory cell 10[i,j] included in a memory layer 11_h+1 is electrically connected to the wiring WBL[i,s] and the wiring RBL[i,s,B]. The memory cell 10[i,j+1] included in the memory layer 11_h+1 is electrically connected to the wiring WBL[i,s+1] and the wiring RBL[i,s,B].

For example, as one of the wiring RBL[i,s,A] and the wiring RBL[i,s,B], a connection electrode that includes the conductors 233b of the odd-numbered memory layers 11 among the conductors 233b of the n memory layers 11 can be used, and the conductors 233b of the odd-numbered memory layers 11 are electrically connected to each other in the connection electrode. As the other of the wiring RBL[i,s,A] and the wiring RBL[i,s,B], for example, a connection electrode that includes the conductors 233b of the even-numbered memory layers 11 among the conductors 233b of the n memory layers 11 can be used, and the conductors 233b of the even-numbered memory layers 11 are electrically connected to each other in the connection electrode.

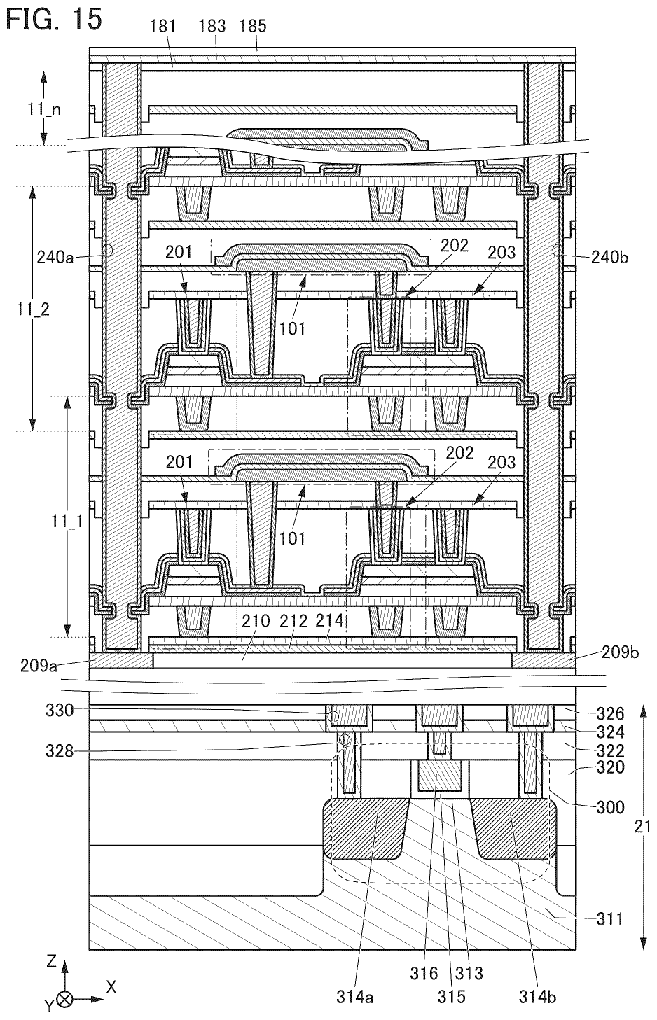

FIG. 15 is a cross-sectional view illustrating a structure example of the semiconductor device of one embodiment of the present invention. The semiconductor device illustrated in FIG. 15 is an example in which a layer including, e.g., a transistor 300 is provided under the structure illustrated in FIG. 8. The transistor 300 can be provided in a driver circuit of a memory cell formed above the insulator 210, for example. Note that the structure above the insulator 210 in FIG. 15 is similar to that in FIG. 8; thus, the detailed description thereof is omitted.

FIG. 15 illustrates an example of the transistor 300. The transistor 300 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 300 may be either a p-channel transistor or an n-channel transistor. As the substrate 311, a single crystal silicon substrate can be used, for example.

Here, in the transistor 300 illustrated in FIG. 15, the semiconductor region 313 (part of the substrate 311) in which a channel is formed has a convex shape. The conductor 316 is provided to cover a side surface and the top surface of the semiconductor region 313 with the insulator 315 therebetween. Note that a material for adjusting the work function may be used as the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI (Silicon on Insulator) substrate.

Note that the transistor 300 illustrated in FIG. 15 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with design. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are stacked in this order over the transistor 300 as an interlayer film. A conductor 328 or the like is embedded in the insulator 320 and the insulator 322. A conductor 330 or the like is embedded in the insulator 324 and the insulator 326. Note that the conductor 328 and the conductor 330 function as a contact plug or a wiring.

The insulators functioning as the interlayer film may also function as a planarization film that covers an uneven shape thereunder. For example, the top surface of the insulator 322 may be planarized by planarization treatment using a chemical mechanical polishing (CMP) method or the like to have improved planarity.

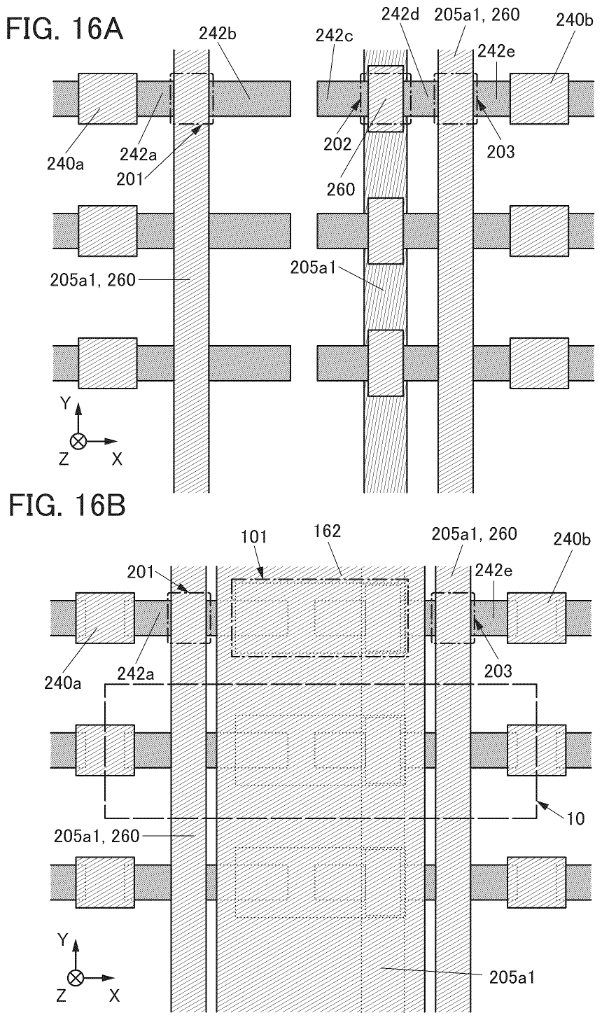

FIG. 16A and FIG. 16B are plan views illustrating examples of the semiconductor device having the structure illustrated in FIG. 10A or the like and illustrate structure examples of the XY plane.

FIG. 16A illustrates the transistor 201, the transistor 202, the transistor 203, the conductor 240a, and the conductor 240b. FIG. 16B illustrates a structure in which the capacitor 101 is added to FIG. 16A. In FIG. 16B, the memory cell 10 is formed by the transistor 201, the transistor 202, the transistor 203, and the capacitor 101. Note that components other than conductors are omitted in FIG. 16A and FIG. 16B.

In FIG. 16A, the conductor 260 included in the transistor 201 includes a region interposed between the conductor 242a and the conductor 242b. The conductor 260 included in the transistor 202 includes a region interposed between the conductor 242c and the conductor 242d. The conductor 260 included in the transistor 203 includes a region interposed between the conductor 242d and the conductor 242e.

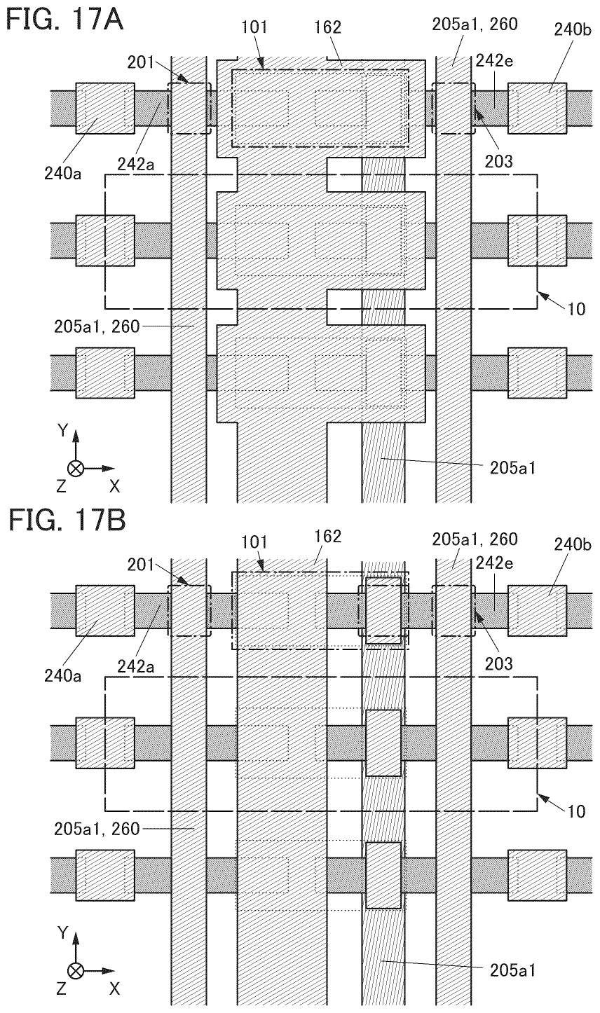

FIG. 17A and FIG. 17B each illustrate an example in which the shape of the conductor 162 is different from that in FIG. 16B. The conductor 162 illustrated in FIG. 17A can have a reduced area overlapping with the conductor 205a1. Thus, the parasitic capacitance between the conductor 162 and the conductor 205a1 can be reduced, for example. The conductor 162 has variations in width in the plan view in FIG. 17A, whereas in FIG. 16B, the width of the conductor 162 can be widened and wiring resistance can be reduced. Alternatively, as illustrated in FIG. 17B, the width of the conductor 162 may be narrowed to reduce a region where the conductor 162 and the conductor 205a1 overlap with each other.

### <Method for Manufacturing Semiconductor Device>

An insulating material for forming an insulator, a conductive material for forming a conductor, or a semiconductor material for forming a semiconductor can be deposited by a sputtering method, a CVD method, an MBE method, a PLD method, an ALD method, or the like as appropriate.

Examples of the sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. The RF sputtering method is mainly used in the case where an insulating film is deposited, and the DC sputtering method is mainly used in the case where a metal conductive film is deposited. The pulsed DC sputtering method is mainly used in the case where a compound such as an oxide, a nitride, or a carbide is deposited by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method is a deposition method that does not use plasma and thus enables less plasma damage to an object to be processed. For example, a wiring, an electrode, an element (a transistor, a capacitor, or the like), or the like included in a semiconductor device may be charged up by receiving electric charges from plasma. In that case, accumulated electric charges might break the wiring, the electrode, the element, or the like included in the semiconductor device. In contrast, such plasma damage is not caused in the case of the thermal CVD method, which does not use plasma, and thus the yield of the semiconductor device can be increased. In addition, the thermal CVD method does not cause plasma damage during deposition, so that a film with few defects can be obtained.

As the ALD method, a thermal ALD method, in which a precursor and a reactant react with each other only by a thermal energy, a PEALD method, in which a reactant excited by plasma is used, and the like can be used.

The CVD method and the ALD method are different from the sputtering method in which particles ejected from a target or the like are deposited. Thus, the CVD method and the ALD method are deposition methods that enable favorable step coverage almost regardless of the shape of an object to be processed. In particular, the ALD method enables excellent step coverage and excellent thickness uniformity and thus is suitable for covering a surface of an opening portion with a high aspect ratio, for example. On the other hand, an ALD method has a relatively low deposition rate, and thus is preferably used in combination with another deposition method with a high deposition rate, such as a CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is deposited while the flow rate ratio of the source gases is changed, as compared with the case where the film is deposited using a plurality of deposition chambers, the time taken for the deposition can be shortened because the time taken for transfer or pressure adjustment is not required. Thus, the productivity of the semiconductor device can be increased in some cases.

By the ALD method, a film with a certain composition can be deposited by concurrently introducing different kinds of precursors. In the case where different kinds of precursors are introduced, a film with a certain composition can be deposited by controlling the number of cycles for each of the precursors.

The insulator 222 can be deposited by a sputtering method, a CVD method, an MBE method, a PLD method, or an ALD method, for example. In this embodiment, for the insulator 222, hafnium oxide is deposited by an ALD method. Alternatively, the insulator 222 may have a stacked-layer structure of silicon nitride deposited by a PEALD method and hafnium oxide deposited by an ALD method.

Heat treatment may be performed after the insulator 222 is formed. The temperature of the heat treatment is preferably higher than or equal to 250° C. and lower than or equal to 650° C., further preferably higher than or equal to 300° C. and lower than or equal to 500° C., still further preferably higher than or equal to 320° C. and lower than or equal to 450° C. Note that the heat treatment is preferably performed in a nitrogen gas or inert gas atmosphere, or an atmosphere containing an oxidizing gas at higher than or equal to 10 ppm, higher than or equal to 1%, or higher than or equal to 10%.

The metal oxide 230a and the metal oxide 230b can each be deposited by a sputtering method, a CVD method, an MBE method, a PLD method, or an ALD method, for example. In this embodiment, the metal oxide 230a and the metal oxide 230b are deposited by a sputtering method.

For example, in the case where the metal oxide 230a and the metal oxide 230b are deposited by a sputtering method, oxygen or a mixed gas of oxygen and a noble gas is used as a sputtering gas. Increasing the proportion of oxygen contained in the sputtering gas can increase the amount of excess oxygen in the deposited oxide films. In the case where the metal oxide 230a and the metal oxide 230b are deposited by a sputtering method, an In-M-Zn oxide target can be used, for example.

The insulator 253 can be deposited by an ALD method, a sputtering method, a CVD method, an MBE method, or a PLD method.

When the insulating film to be the insulator 253 is deposited by an ALD method, ozone (O₃), oxygen (O₂), water (H₂O), or the like can be used as the oxidizer. When an oxidizer without containing hydrogen, such as ozone (O₃) or oxygen (O₂), is used, the amount of hydrogen diffusing into the metal oxide 230b can be reduced.

This embodiment can be combined with the other embodiments as appropriate. In this specification, in the case where a plurality of structure examples are described in one embodiment, the structure examples can be combined as appropriate.

### Embodiment 3

In this embodiment, an example of a chip on which the memory device of one embodiment of the present invention is mounted will be described with reference to drawings.

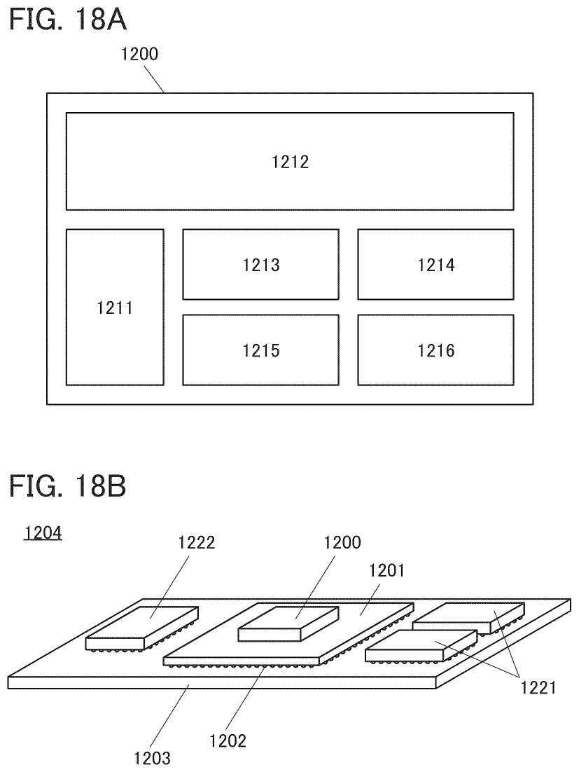

A plurality of circuits (systems) are mounted on a chip 1200 illustrated in FIG. 18A and FIG. 18B. A technology for integrating a plurality of circuits (systems) into one chip is referred to as system on chip (SoC) in some cases.

As illustrated in FIG. 18A, the chip 1200 includes a CPU 1211, a GPU 1212, one or more analog arithmetic units 1213, one or more memory controllers 1214, one or more interfaces 1215, one or more network circuits 1216, and the like.

The chip 1200 is provided with a bump (not illustrated) and is connected to a first surface of a package substrate 1201 as illustrated in FIG. 18B. In addition, a plurality of bumps 1202 are provided on a rear side of the first surface of the package substrate 1201, and the package substrate 1201 is connected to a motherboard 1203.

Memory devices such as a DRAM 1221 and a flash memory 1222 may be provided over the motherboard 1203. For example, the memory circuit described in the above embodiment can be used as the DRAM 1221. This can make the DRAM 1221 have a large capacity, operate at high speed, and have low power consumption.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The memory circuit described above can be used as the memory. Moreover, the GPU 1212 is suitable for parallel computation of a number of data and thus can be used for image processing or product-sum operation. When an image processing circuit or a product-sum operation circuit using an OS transistor is provided in the GPU 1212, image processing or product-sum operation can be performed with low power consumption.

In addition, since the CPU 1211 and the GPU 1212 are provided in the same chip, a wiring between the CPU 1211 and the GPU 1212 can be shortened; accordingly, data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAM 1221, and the flash memory 1222 can be referred to as a GPU module 1204.

The GPU module 1204 includes the chip 1200 formed using the SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with the other embodiments as appropriate.

### Embodiment 4

In this embodiment, examples of electronic components incorporating the memory device of one embodiment of the present invention are described.

### [Electronic Component]

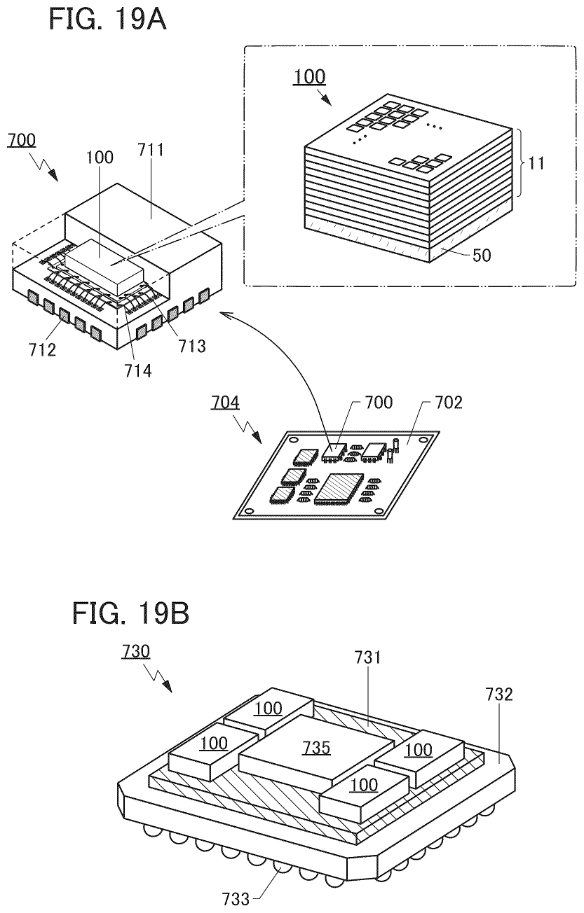

FIG. 19A illustrates a perspective view of an electronic component 700 and a substrate (a mounting board 704) on which the electronic component 700 is mounted. The electronic component 700 illustrated in FIG. 19A includes the memory device 100, which is the memory device of one embodiment of the present invention, in a mold 711. FIG. 19A omits illustrations of some parts to show the inside of the electronic component 700. The electronic component 700 includes a land 712 outside the mold 711. The land 712 is electrically connected to an electrode pad 713, and the electrode pad 713 is electrically connected to the memory device 100 via a wire 714. The electronic component 700 is mounted on a printed circuit board 702, for example. A plurality of such electronic components are combined and electrically connected to each other on the printed circuit board 702, whereby the mounting board 704 is completed.

As described in the above embodiment, the memory device 100 includes the driver circuit layer 50 and the memory layers 11 (each including the memory cell array 15).

FIG. 19B illustrates a perspective view of an electronic component 730. The electronic component 730 is an example of a SiP (System in package) or an MCM (Multi Chip Module). In the electronic component 730, an interposer 731 is provided over a package substrate 732 (a printed circuit board) and a semiconductor device 735 and a plurality of memory devices 100 are provided over the interposer 731.

The electronic component 730 using the memory device 100 as a high bandwidth memory (HBM) is illustrated as an example. An integrated circuit (a semiconductor device) such as a CPU, a GPU, or an FPGA can be used as the semiconductor device 735.

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer, a TSV (Through Silicon Via) can also be used as the through electrode.

A silicon interposer is preferably used as the interposer 731. The silicon interposer can be manufactured at lower cost than an integrated circuit because it is not necessary to provide an active element. Moreover, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (a radiator plate) may be provided to overlap with the electronic component 730. In the case of providing a heat sink, the heights of integrated circuits provided on the interposer 731 are preferably equal to each other. In the electronic component 730 of this embodiment, the heights of the memory device 100 and the semiconductor device 735 are preferably equal to each other, for example.

An electrode 733 may be provided on the bottom portion of the package substrate 732 to mount the electronic component 730 on another substrate. FIG. 19B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

This embodiment can be combined with the other embodiments as appropriate.

### Embodiment 5

In this embodiment, application examples of the memory device of one embodiment of the present invention are described.

The memory device of one embodiment of the present invention can be applied to memory devices of a variety of electronic devices (e.g., information terminals, computers, smartphones, e-book readers, digital still cameras, video cameras, video recording/reproducing devices, navigation systems, and game machines). In addition, the memory device can also be used for image sensors, IoT (Internet of Things), healthcare-related devices, and the like. Note that, here, the computers refer not only to tablet computers, laptop computers, and desktop computers but also to large computers such as server systems.

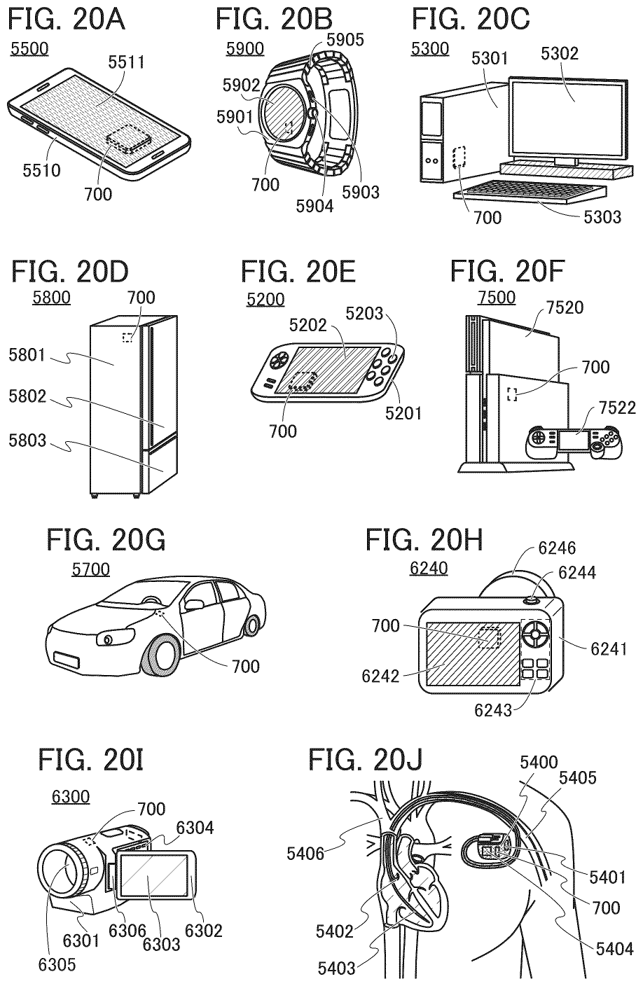

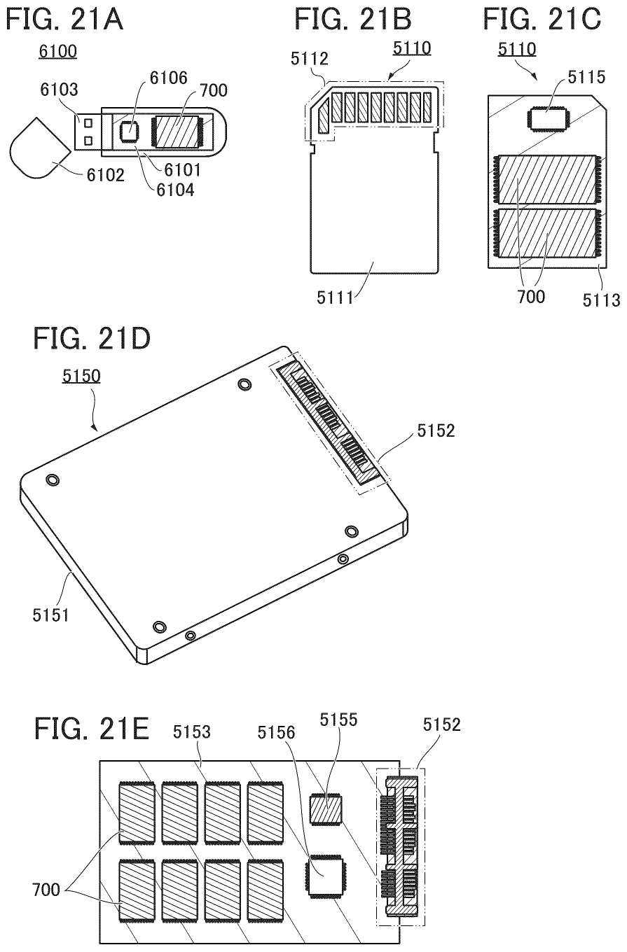

Examples of electronic devices including the memory device of one embodiment of the present invention are described. Note that FIG. 20A to FIG. 20J and FIG. 21A to FIG. 21E each illustrate a state where the electronic component 700 or the electronic component 730, which is described in the above embodiment and includes the memory device, is included in an electronic device.

### [Mobile Phone]

An information terminal 5500 illustrated in FIG. 20A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

By using the memory device of one embodiment of the present invention, the information terminal 5500 can retain a temporary file generated at the time of executing an application (e.g., a web browser's cache or the like).

### [Wearable Terminal]

FIG. 20B illustrates an information terminal 5900, which is an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by using the memory device of one embodiment of the present invention.

### [Information Terminal]

FIG. 20C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application by using the memory device of one embodiment of the present invention.

FIG. 20A to FIG. 20C illustrate the smartphone, the wearable terminal, and the desktop information terminal as electronic devices; other examples of information terminals include a PDA (Personal Digital Assistant), a laptop information terminal, and a workstation.

### [Household Appliance]

FIG. 20D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The memory device of one embodiment of the present invention can be applied to the electric refrigerator-freezer 5800. The electric refrigerator-freezer 5800 can transmit and receive information on food stored in the electric refrigerator-freezer 5800 and food expiration dates, for example, to and from an information terminal via the Internet. In the electric refrigerator-freezer 5800, the memory device of one embodiment of the present invention can retain a temporary file generated at the time of transmitting the information.

FIG. 20D illustrates the electric refrigerator-freezer as a household appliance; other examples of household appliances include a vacuum cleaner, a microwave oven, an electric oven, a rice cooker, a water heater, an IH cooker, a water server, a heating-cooling combination appliance including an air conditioner, a washing machine, a drying machine, and an audio visual appliance.

### [Game Machine]

FIG. 20E illustrates a portable game machine 5200, which is an example of a game machine. The portable game machine 5200 includes a housing 5201, a display portion 5202, a button 5203, and the like.

FIG. 20F illustrates a stationary game machine 7500, which is an example of a game machine. The stationary game machine 7500 can be especially referred to as a home-use stationary game machine. The stationary game machine 7500 includes a main body 7520 and a controller 7522. Note that the controller 7522 can be connected to the main body 7520 with or without a wire. Although not illustrated in FIG. 20F, the controller 7522 can include a display portion that displays a game image, and an input interface besides a button, such as a touch panel, a stick, a rotating knob, or a sliding knob, for example. The shape of the controller 7522 is not limited to that illustrated in FIG. 20F, and the shape of the controller 7522 may be changed in various ways in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include one or more of a camera, a depth sensor, and a microphone so that the game player can play a game using a gesture or a voice instead of a controller.

In addition, videos displayed on the game machine can be output with a display device such as a television device, a personal computer display, a game display, or a head-mounted display.

By using the memory device of one embodiment of the present invention, the portable game machine 5200 or the stationary game machine 7500 can achieve low power consumption. Moreover, heat generation from a circuit can be reduced owing to the low power consumption; thus, the influence of heat generation on the circuit itself, a peripheral circuit, and a module can be reduced.

Moreover, by using the memory device of one embodiment of the present invention, the portable game machine 5200 or the stationary game machine 7500 can retain a temporary file necessary for arithmetic operation that occurs during game play.

FIG. 20E and FIG. 20F illustrate the portable game machine and the home-use stationary game machine as examples of game machines; other examples of game machines include an arcade game machine installed in an entertainment facility (e.g., a game center and an amusement park) and a throwing machine for batting practice, installed in sports facilities.

### [Moving Vehicle]

The memory device of one embodiment of the present invention can be applied to an automobile, which is a moving vehicle, and the periphery of a driver's seat in the automobile.

FIG. 20G illustrates an automobile 5700, which is an example of a moving vehicle.

An instrument panel that displays various kinds of information such as a speedometer, a tachometer, a mileage, a fuel meter, a gearshift state, air-conditioning settings, and the like is provided around the driver's seat in the automobile 5700. In addition, a memory device showing the above information may be provided around the driver's seat.

In particular, the display device can compensate for the view obstructed by the pillar, for example, the blind areas for the driver's seat, and the like by displaying a video taken by an imaging device (not illustrated) provided for the automobile 5700, thereby providing a high level of safety. That is, display of an image from an imaging device provided on the outside of the automobile 5700 can fill in blind areas and increase safety.

The memory device of one embodiment of the present invention can temporarily retain information; thus, the memory device can be used to retain temporary information necessary in a system conducting automatic driving, navigation, risk prediction, or the like for the automobile 5700, for example. Moreover, the memory device of one embodiment of the present invention may be configured to retain a video of a driving recorder provided in the automobile 5700.

Although the automobile is described above as an example of a moving vehicle, the moving vehicle is not limited to the automobile. Examples of moving vehicles include a train, a monorail train, a ship, and a flying object (a helicopter, an unmanned aircraft (drone), an airplane, or a rocket).

### [Camera]

The memory device of one embodiment of the present invention can be applied to a camera.

FIG. 20H illustrates a digital camera 6240, which is an example of an imaging device. The digital camera 6240 includes a housing 6241, a display portion 6242, operation switches 6243, a shutter button 6244, and the like, and a detachable lens 6246 is attached to the digital camera 6240. Note that, here, although the digital camera 6240 is configured such that the lens 6246 is detachable from the housing 6241 for replacement, the lens 6246 may be integrated with the housing 6241. In addition, the digital camera 6240 can be additionally equipped with a stroboscope, a viewfinder, or the like.

By using the memory device of one embodiment of the present invention, the digital camera 6240 can achieve low power consumption. Moreover, heat generation from a circuit can be reduced owing to the low power consumption; thus, the influence of heat generation on the circuit itself, a peripheral circuit, and a module can be reduced.

### [Video Camera]

The memory device of one embodiment of the present invention can be applied to a video camera.

FIG. 20I illustrates a video camera 6300, which is an example of an imaging device. The video camera 6300 includes a first housing 6301, a second housing 6302, a display portion 6303, operation switches 6304, a lens 6305, and a joint 6306. The operation switches 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Videos displayed on the display portion 6303 may be changed in accordance with the angle at the joint 6306 between the first housing 6301 and the second housing 6302.

When videos taken by the video camera 6300 are recorded, the videos need to be encoded in accordance with a data recording format. By using the memory device of one embodiment of the present invention, the video camera 6300 can retain a temporary file generated at the time of encoding.

### [ICD]

The memory device of one embodiment of the present invention can be applied to an implantable cardioverter-defibrillator (ICD).

FIG. 20J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 functions as a pacemaker and paces the heart when the heart rate is not within a predetermined range. In addition, when the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In the ICD main unit 5400, data on the heart rate obtained by the sensor, the number of times the treatment with pacing is performed, or the time taken for the treatment, for example, can be stored in the electronic component 700.

In addition, the antenna 5404 can receive power, and the battery 5401 is charged with the power. Furthermore, when the ICD main unit 5400 includes a plurality of batteries, safety can be increased. Specifically, even when some of the batteries in the ICD main unit 5400 are dead, the other batteries can function properly; thus, the batteries also function as an auxiliary power source.

In addition to the antenna 5404 capable of receiving power, an antenna that can transmit physiological signals may be included to construct, for example, a system that monitors cardiac activity by checking physiological signals such as a pulse, a respiratory rate, a heart rate, and body temperature with an external monitoring device.

### [Expansion Device for PC]

The memory device of one embodiment of the present invention can be applied to a computer such as a PC (Personal Computer) and an expansion device for an information terminal.

FIG. 21A illustrates, as an example of the expansion device, a portable expansion device 6100 that includes a chip capable of storing information and is externally provided on a PC. The expansion device 6100 can store information using the chip when connected to a PC with a USB (Universal Serial Bus), for example. Note that FIG. 21A illustrates the portable expansion device 6100; however, the expansion device of one embodiment of the present invention is not limited thereto and may be a comparatively large expansion device including a cooling fan, for example.

The expansion device 6100 includes a housing 6101, a cap 6102, a USB connector 6103, and a substrate 6104. The substrate 6104 is held in the housing 6101. The substrate 6104 is provided with a circuit for driving the memory device of one embodiment of the present invention, for example. For example, the substrate 6104 is provided with the electronic component 700 and a controller chip 6106. The USB connector 6103 functions as an interface for connection to an external device.

### [SD Card]

The memory device of one embodiment of the present invention can be applied to an SD card that can be attached to an electronic device such as an information terminal or a digital camera.

FIG. 21B is a schematic external view of an SD card, and FIG. 21C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, the electronic components 700 and a controller chip 5115 are attached to the substrate 5113. Note that the circuit structures of the electronic components 700 and the controller chip 5115 are not limited to those described above, and can be changed as appropriate according to circumstances. For example, a write circuit, a row driver, a read circuit, or the like provided in an electronic component may be incorporated into the controller chip 5115 instead of the electronic component 700.

When the electronic components 700 are provided also on a rear surface side of the substrate 5113, the capacity of the SD card 5110 can be increased. In addition, a wireless chip with a wireless communication function may be provided on the substrate 5113. This allows wireless communication between an external device and the SD card 5110 and enables data reading and writing from and to the electronic components 700.

### [SSD]

The memory device of one embodiment of the present invention can be applied to an SSD (Solid State Drive) that can be attached to an electronic device such as an information terminal.

FIG. 21D is a schematic external view of an SSD, and FIG. 21E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device. For example, the electronic components 700, a memory chip 5155, and a controller chip 5156 are attached to the substrate 5153. When the electronic components 700 are also provided on a rear surface side of the substrate 5153, the capacity of the SSD 5150 can be increased. A work memory is incorporated in the memory chip 5155. For example, a DRAM chip is used as the memory chip 5155. A processor, an ECC (Error-Correcting Code) circuit, and the like are incorporated into the controller chip 5156. Note that the circuit structures of the electronic components 700, the memory chip 5155, and the controller chip 5115 are not limited to those described above, and the circuit structures can be changed as appropriate according to circumstances. For example, a memory functioning as a work memory may also be provided in the controller chip 5156.

### [Computer]

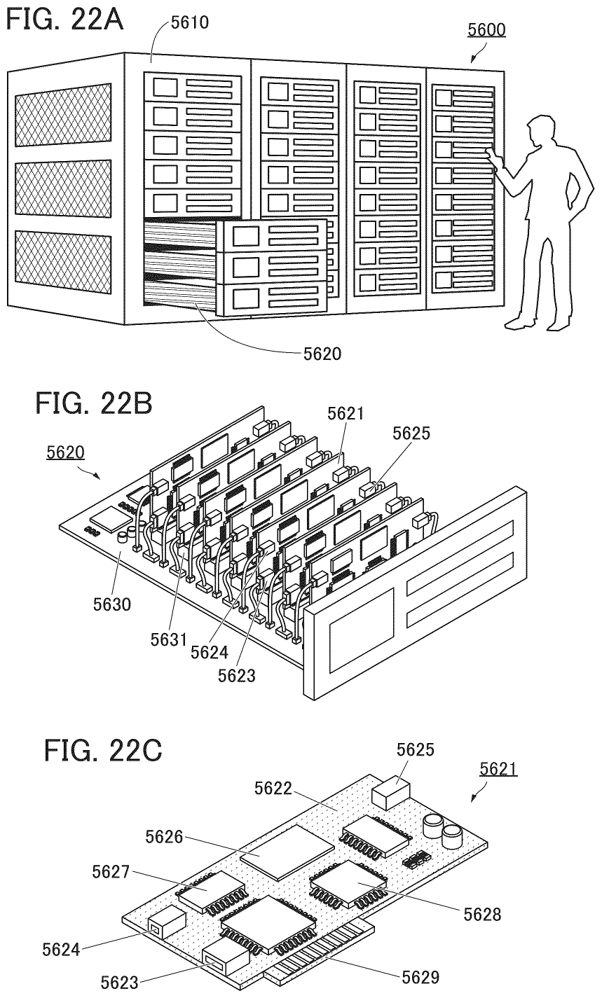

A computer 5600 illustrated in FIG. 22A is an example of a large computer. In the computer 5600, a plurality of rack mount computers 5620 are stored in a rack 5610.

The computer 5620 can have a structure in a perspective view illustrated in FIG. 22B, for example. In FIG. 22B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 22C is an example of a processing board provided with a CPU, a GPU, a memory device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 22C also illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal computed by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, a CPU, and the like. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

The memory device of one embodiment of the present invention is used in a variety of electronic devices or the like described above, so that a reduction in size and a reduction in power consumption of the electronic device can be achieved. In addition, since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention can achieve an electronic device that operates stably even in a high temperature environment. Thus, the reliability of the electronic device can be increased.

This embodiment can be combined with the other embodiments as appropriate.

### Embodiment 6

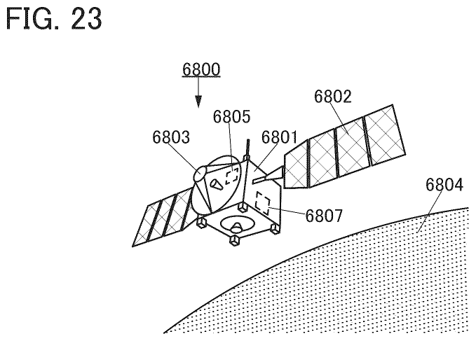

In this embodiment, a specific example of a case where the semiconductor device of one embodiment of the present invention is applied to a device for space is described with reference to FIG. 23.

The semiconductor device of one embodiment of the present invention includes an OS transistor. A change in electrical characteristics of the OS transistor due to exposure to radiation is small. That is, the OS transistor is highly resistant to radiation, and thus can be suitably used even in an environment where radiation can enter. For example, the OS transistor can be suitably used in outer space.

FIG. 23 illustrates an artificial satellite 6800 as an example of a device for space. The artificial satellite 6800 includes a body 6801, a solar panel 6802, an antenna 6803, a secondary battery 6805, and a control device 6807. Note that FIG. 23 illustrates a planet 6804 in outer space, for example. Note that outer space refers to, for example, space at an altitude greater than or equal to 100 km, and outer space described in this specification may include one or more of thermosphere, mesosphere, and stratosphere.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in the situation where the solar panel is not irradiated with sunlight or the amount of sunlight with which the solar panel is irradiated is small, the amount of generated electric power is small. Accordingly, a sufficient amount of electric power required for the operation of the artificial satellite 6800 might not be generated. In order to operate the artificial satellite 6800 even with a small amount of generated electric power, the artificial satellite 6800 is preferably provided with the secondary battery 6805. Note that the solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor, which is one embodiment of the present invention, is suitably used for the control device 6807. A change in electrical characteristics due to exposure to radiation is smaller in the OS transistor than in a Si transistor. Accordingly, the OS transistor has high reliability and thus can be suitably used even in an environment where radiation can enter.

Alternatively, the artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of a device for space in this embodiment, the present invention is not limited thereto. The semiconductor device of one embodiment of the present invention can be suitably used for a device for space such as a spacecraft, a space capsule, or a space probe, for example.

### REFERENCE NUMERALS

10: memory cell, 11: memory layer, 15: memory cell array, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: driver circuit layer, 100: memory device, 101: capacitor, 101b: capacitor, 160: conductor, 161: conductor, 162: conductor, 163: insulator, 181: insulator, 183: insulator, 185: insulator, 201: transistor, 202: transistor, 203: transistor, 205a: conductor, 205b: conductor, 205: conductor, 209a: conductor, 209b: conductor, 209: conductor, 210: insulator, 212: insulator, 214: insulator, 215: insulator, 215F: insulator, 216a: insulator, 216b: insulator, 222: insulator, 222F: insulator, 224: insulator, 230a: metal oxide, 230b: metal oxide, 230: metal oxide, 231: conductor, 232: conductor, 233a: conductor, 233b: conductor, 240a: conductor, 240b: conductor, 240c: connection electrode, 240d: connection electrode, 240: conductor, 242a: conductor, 242b: conductor, 242c: conductor, 242d: conductor, 242e: conductor, 242: conductor, 253: insulator, 254: insulator, 258: opening, 260: conductor, 275: insulator, 280: insulator, 282: insulator, 285: insulator, 287: insulator, 288: insulator, 291a: opening, 291b: opening, 292a: opening, 292b: opening, 293a: opening, 293b: opening, 294a: opening, 294b: opening, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 700: electronic component, 702: printed circuit board, 704: mounting board, 711: mold, 712: land, 713: electrode pad, 714: wire, 730: electronic component, 731: interposer, 732: package substrate, 733: electrode, 735: semiconductor device, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5110: SD card, 5111: housing, 5112: connector, 5113: substrate, 5115: controller chip, 5150: SSD, 5151: housing, 5152: connector, 5153: substrate, 5155: memory chip, 5156: controller chip, 5200: portable game machine, 5201: housing, 5202: display portion, 5203: button, 5300: desktop information terminal, 5301: main body, 5302: display portion, 5303: keyboard, 5400: ICD main unit, 5401: battery, 5402: wire, 5403: wire, 5404: antenna, 5405: subclavian vein, 5406: superior vena cava, 5500: information terminal, 5510: housing, 5511: display portion, 5600: computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5700: automobile, 5800: electric refrigerator-freezer, 5801: housing, 5802: refrigerator door, 5803: freezer door, 5900: information terminal, 5901: housing, 5902: display portion, 5903: operation switch, 5904: operation switch, 5905: band, 6100: expansion device, 6101: housing, 6102: cap, 6103: USB connector, 6104: substrate, 6106: controller chip, 6240: digital camera, 6241: housing, 6242: display portion, 6243: operation switch, 6244: shutter button, 6246: lens, 6300: video camera, 6301: first housing, 6302: second housing, 6303: display portion, 6304: operation switch, 6305: lens, 6306: joint, 6800: artificial satellite, 6801: body, 6802: solar panel, 6803: antenna, 6804: planet, 6805: secondary battery, 6807: control device, 7500: stationary game machine, 7520: main body, 7522: controller

1. A semiconductor device comprising:
a first transistor, a second transistor, and a capacitor,
wherein the first transistor comprises a first insulator, a first metal oxide over the first insulator, a second insulator over the first metal oxide, a first conductor over the second insulator, a second conductor covering part of a top surface and part of a side surface of the first metal oxide, and a third conductor covering part of the top surface and part of the side surface of the first metal oxide,
wherein the second transistor comprises the first insulator, the first metal oxide over the first insulator, a third insulator over the first metal oxide, a fourth conductor over the third insulator, the third conductor, and a fifth conductor covering part of the top surface and part of the side surface of the first metal oxide,
wherein the third conductor is shared by the first transistor and the second transistor,
wherein the first metal oxide is shared by the first transistor and the second transistor,
wherein the first metal oxide comprises a channel formation region of the first transistor and a channel formation region of the second transistor,
wherein the first insulator comprises a region overlapping with the first metal oxide,
wherein the capacitor comprises a sixth conductor, a seventh conductor, and a material configured to have ferroelectricity between the sixth conductor and the seventh conductor, and
wherein the first conductor and the sixth conductor are electrically connected to each other.

2. The semiconductor device according to claim 1,
wherein the material configured to have ferroelectricity is one or more selected from hafnium oxide, zirconium oxide, and HfZrO_{X}, and
wherein X is a real number greater than 0.

3. The semiconductor device according to claim 1,
wherein the material configured to have ferroelectricity is a material comprising oxygen, hafnium, and zirconium.

4. The semiconductor device according to claim 1,
wherein the material configured to have ferroelectricity is a material where one or more selected from zirconium, silicon, aluminum, gadolinium, yttrium, lanthanum, and strontium are added to hafnium oxide.

5. The semiconductor device according to claim 1,
wherein the material configured to have ferroelectricity is a material where one or more selected from hafnium, silicon, aluminum, gadolinium, yttrium, lanthanum, and strontium are added to zirconium oxide.

6. The semiconductor device according to claim 1,
wherein at least one of the sixth conductor and the seventh conductor comprises titanium nitride.

7. The semiconductor device according to claim 1,
wherein the third conductor comprises a region interposed between the first conductor and the fourth conductor in a plan view.

8. The semiconductor device according to claim 1, further comprising a third transistor,
wherein the first insulator comprises a material configured to have ferroelectricity,
wherein the third transistor comprises an eighth conductor, the first insulator over the eighth conductor, a second metal oxide over the first insulator, a fifth insulator over the second metal oxide, a ninth conductor over the fifth insulator, and the sixth conductor covering part of a top surface and part of a side surface of the second metal oxide,
wherein the sixth conductor comprises a region in contact with a top surface of the first insulator,
wherein the seventh conductor comprises a region in contact with a bottom surface of the first insulator,
wherein the eighth conductor comprises a region in contact with the bottom surface of the first insulator, and
wherein the first insulator comprises a region overlapping with the second metal oxide and a region overlapping with the seventh conductor.

9. The semiconductor device according to claim 8,
wherein the seventh conductor and the eighth conductor each comprise titanium nitride.

10. The semiconductor device according to claim 1, further comprising a plurality of memory layers stacked sequentially,
wherein each of the plurality of memory layers comprises the first transistor, the second transistor, and the capacitor, and
wherein the fifth conductor of the second transistor included in each of the plurality of memory layers is electrically connected to the fifth conductor of the second transistor included in another memory layer.
